(19) United States
(12) Patent Application Publication
(10) Pub. No.: US 2024/0315039 A1
(43) Pub. Date: Sep. 19, 2024

(54) SEMICONDUCTOR DEVICES AND MANUFACTURING METHODS OF THE SAME, AND ELECTRONIC SYSTEMS INCLUDING SEMICONDUCTOR DEVICES

(71) Applicant: SAMSUNG ELECTRONICS CO., LTD., Suwon-si (KR)

(72) Inventors: Gyeongsik EOM, Suwon-si (KR); Inho KIM, Suwon-si (KR); Chankyu KIM, Suwon-si (KR); Jumi YUN, Suwon-si (KR); Young-Ho LEE, Suwon-si (KR); Dasom JUNG, Suwon-si (KR); Wongi HONG, Suwon-si (KR)

(21) Appl. No.: 18/483,331

(22) Filed: Oct. 9, 2023

(30) Foreign Application Priority Data
Mar. 14, 2023 (KR) 10-2023-0033346

(51) Int. Cl. H10B 43/40; H01L 25/065; H10B 41/10; H10B 41/27; H10B 41/35; H10B 41/40; H10B 43/10; H10B 43/27; H10B 43/35; H10B 80/00

(52) U.S. Cl. CPC H10B 43/40; H01L 25/0652; H10B 41/10; H10B 41/27; H10B 41/35; H10B 41/40; H10B 43/10; H10B 43/27; H10B 43/35; H10B 80/00; H01L 2225/06506

(57) ABSTRACT

A semiconductor device includes a cell area, wherein the cell area includes: a cell array area; a connection area; a gate stacking structure including a plurality of gate electrodes, wherein the gate stacking structure includes an upper structure and a lower structure; a plurality of channel structures that penetrates the gate stacking structure in the cell array area; and a plurality of gate contact portions that penetrates the gate stacking structure in the connection area, wherein a bottom gate electrode in the cell array area is in a bottom portion of the upper structure and is adjacent to a channel structure among the plurality of channel structures, and wherein a bottom insulating portion in the connection area is in the bottom portion of the upper structure and is adjacent to a gate contact portion among the plurality of gate contact portions.

### CROSS-REFERENCE TO RELATED APPLICATION

This application claims priority to and the benefit of Korean Patent Application No. 10-2023-0033346 filed in the Korean Intellectual Property Office on Mar. 14, 2023, the entire contents of which are incorporated herein by reference.

### BACKGROUND

The present disclosure relates to semiconductor devices, and manufacturing methods thereof, and electronic systems including the semiconductor devices.

In an electronic system that requires data storage, a semiconductor device capable of storing high-capacity data may be required. Accordingly, methods for increasing the data storage capacity of a semiconductor device are being researched. For example, as one of the methods for increasing the data storage capacity of a semiconductor device, a semiconductor device including three-dimensionally arranged memory cells instead of two-dimensionally arranged memory cells has been proposed.

### SUMMARY

An embodiment seeks to provide a semiconductor device and a manufacturing method capable of improving reliability and productivity, and an electronic system including the semiconductor device.

A semiconductor device comprising: a circuit area including a peripheral circuit structure; and a cell area on the circuit area, wherein the cell area includes: a cell array area; a connection area; a gate stacking structure including a plurality of gate electrodes, wherein the gate stacking structure includes an upper structure on the circuit area and a lower structure between the upper structure and the circuit area; a plurality of channel structures that penetrates the gate stacking structure in the cell array area; and a plurality of gate contact portions that penetrates the gate stacking structure in the connection area, wherein the plurality of gate electrodes comprises a bottom gate electrode in a bottom portion of the upper structure, wherein a gate contact portion among the plurality of gate contact portions is electrically connected to the circuit area and a connection gate electrode of the plurality of gate electrodes and is electrically insulated from remaining gate electrodes of the plurality of gate electrodes by an insulating pattern between the gate contact portion and the remaining gate electrodes, wherein the bottom gate electrode in the cell array area is adjacent to a channel structure among the plurality of channel structures, and wherein a bottom insulating portion having a structure and/or a material different from the insulating pattern is in the bottom portion of the upper structure and adjacent to the gate contact portion.

An electronic system comprising: a main substrate; a semiconductor device on the main substrate; and a controller electrically connected to the semiconductor device, wherein the semiconductor device includes a circuit area including a peripheral circuit structure, and a cell area on the circuit area, and wherein the cell area includes: a cell array area; a connection area; a gate stacking structure including a plurality of gate electrodes, wherein the gate stacking structure includes a lower structure and an upper structure on the lower structure; and a channel structure that penetrates the gate stacking structure in the cell array area, wherein the plurality of gate electrodes includes a bottom gate electrode in a bottom portion of the upper structure, wherein a gate contact portion in the connection area is electrically connected to the circuit area and a connection gate electrode of the plurality of gate electrodes and is electrically insulated from remaining gate electrodes of the plurality of gate electrodes by an insulating pattern between the gate contact portion and the remaining gate electrodes, wherein the bottom gate electrode in the cell array area is adjacent to the channel structure, and wherein a bottom insulating portion having a structure and/or a material different from the insulating pattern is in the bottom portion of the upper structure and adjacent to the gate contact portion.

A manufacturing method of a semiconductor device; the manufacturing method comprising: forming a lower structure by alternately stacking a first plurality of sacrificial insulation layers and a first plurality of insulation layers on a circuit area that includes a peripheral circuit structure; forming a first channel sacrificial layer and a first wire sacrificial layer in the lower structure; forming a bottom sacrificial insulation layer on the lower structure; forming a gate removed portion by at least partially removing an area of the bottom sacrificial insulation layer on the first wire sacrificial layer; forming an insulating material on the bottom sacrificial insulation layer to form a bottom insulation layer including a bottom insulating portion filling the gate removed portion and an interlayer insulating layer on the bottom sacrificial insulation layer; forming an upper structure by alternately stacking a second plurality of sacrificial insulation layers and a second plurality of insulation layers on the bottom insulation layer; forming a second channel sacrificial layer and a second wire sacrificial layer; removing the first and second channel sacrificial layers, the first and second wire sacrificial layers, the first plurality of sacrificial insulation layers, the bottom sacrificial insulation layer, and the second plurality of insulation sacrificial layers; and forming a channel structure, a gate contact portion, and a plurality of gate electrodes from which the first and second channel sacrificial layers, the first and second wire sacrificial layers, the first plurality of sacrificial insulation layers, the bottom sacrificial insulation layer, and the second plurality of insulation sacrificial layers are removed.

A semiconductor device comprising: a circuit area including a peripheral circuit structure; and a cell area on the circuit area, wherein the cell area includes: a cell array area; a connection area that is adjacent to the cell array area; a gate stacking structure including a plurality of gate electrodes, wherein the gate stacking structure includes an upper structure on the circuit area and a lower structure between the upper structure and the circuit area; a plurality of channel structures that penetrates the gate stacking structure in the cell array area; and a plurality of gate contact portions that penetrates the gate stacking structure in the connection area, wherein the plurality of gate electrodes comprises a bottom gate electrode in a bottom portion of the upper structure, wherein a gate contact portion among the plurality of gate contact portions is electrically connected to the circuit area and a connection gate electrode of the plurality of gate electrodes and is electrically insulated from remaining gate electrodes of the plurality of gate electrodes by an insulating pattern between the gate contact portion and the remaining gate electrodes, wherein the bottom portion of the upper structure includes a first bottom portion adjacent to a channel structure among the plurality of channel structures in the cell array area, wherein the bottom portion of the upper structure includes a second bottom portion adjacent to the gate contact portion in the connection area, and wherein the first bottom portion includes a structure and/or a material different from the second bottom portion.

According to an embodiment, the channel structure and the part adjacent to the gate contact portion has the different structures or materials, so that the channel structure and the gate contact portion may satisfy the required properties, respectively. That is, the number of memory cells may be maximized by positioning the bottom gate electrode at the portion adjacent to the channel structure, and the channel structure may be stably connected by sufficiently securing the bottom threshold size of the channel structure. In addition, the bottom insulating portion may be positioned adjacent to the gate contact portion to sufficiently secure an insulating distance between the gate contact portion and the bottom gate electrode, thereby effectively preventing problems caused by deviated or misaligned gate contact portions.

Also, as described above, the semiconductor device capable of meeting the required properties in the channel structure and the gate contact portion may be manufactured by a simple process. Accordingly, the productivity and reliability of semiconductor devices may be improved.

### BRIEF DESCRIPTION OF THE DRAWINGS

FIG. 1 illustrates a partial plan view of a semiconductor device according to some embodiments.

FIG. 2 illustrates partial cross-sectional views of the semiconductor device of FIG. 1 taken along lines A-A′, B-B′, and C-C′.

FIG. 3 illustrates partial cross-sectional views of a channel structure included in the semiconductor device shown in FIG. 1 according to some embodiments.

FIG. 4 illustrates a partial cross-sectional view of the semiconductor device of FIG. 1 taken along a line D-D′.

FIG. 5 illustrates a partial plan view showing a surface corresponding to an upper surface of a bottom gate electrode in the semiconductor device shown in FIG. 1.

FIGS. 6A and 6B illustrate enlarged views of a portion E and a portion F of FIG. 5, respectively.

FIGS. 7A and 7B illustrate enlarged views of a portion G and a portion H of FIG. 2, respectively.

FIGS. 8A, 8B, 8C, 8D, 8E, 8F, 8G, 8H, and 8I illustrate partial cross-sectional views showing a manufacturing method of a semiconductor device according to some embodiments.

FIG. 9 illustrates a partial plan view showing a surface corresponding to an upper surface of a bottom gate electrode in a semiconductor device according to some embodiments.

FIG. 10 illustrates a partial plan view showing a surface corresponding to an upper surface of a bottom gate electrode in a semiconductor device according to some embodiments.

FIGS. 11A and 11B illustrate enlarged views of a part of a cell array area and a part of a connection area in a semiconductor device according to some embodiments.

FIG. 12 illustrates a partial plan view showing a surface corresponding to an upper surface of a bottom gate electrode in a semiconductor device according to some embodiments.

FIG. 13 illustrates partial cross-sectional views showing a semiconductor device according to some embodiments.

FIG. 14 illustrates a partial cross-sectional view showing a semiconductor device according to some embodiments.

FIG. 15 illustrates a view schematically showing an electronic system including a semiconductor device according to some embodiments.

FIG. 16 illustrates perspective views schematically showing an electronic system including a semiconductor device according to some embodiments.

FIG. 17 illustrates cross-sectional views showing a semiconductor package according to some embodiments.

FIG. 18 illustrates cross-sectional views showing a semiconductor package according to some embodiments.

### DETAILED DESCRIPTION

The present disclosure will be described more fully hereinafter with reference to the accompanying drawings, in which embodiments of the disclosure are shown. As those skilled in the art would realize, the described embodiments may be modified in various different ways, all without departing from the scope of the present disclosure.

In order to clarify the present disclosure, parts that are not connected with the description may be omitted, and the same elements or equivalents may be referred to by the same reference numerals throughout the specification unless clearly described otherwise.

Further, since sizes and thicknesses of constituent members shown in the accompanying drawings may be exaggerated or scaled down for better understanding and ease of description, the present disclosure is not limited to the illustrated sizes and thicknesses. For example, in the drawings, the thickness of layers, films, panels, areas, etc., may be exaggerated for clarity. In the drawings, for better understanding and ease of description, thicknesses of some layers and areas may be excessively displayed.

It will be understood that when a layer, film, region, plate, or the like may be disposed “on” or “on a top” of another layer, film, region, plate, or the like, the former may directly contact the latter or still another layer, film, region, plate, or the like may be disposed between the former and the latter. As used herein, when a layer, film, region, plate, or the like is disposed “directly on” or “directly on a top” of another layer, film, region, plate, or the like, the former directly contacts the latter and still another layer, film, region, plate, or the like is not disposed between the former and the latter. Further, as used herein, when a layer, film, region, plate, or the like may be disposed “below” or “under” another layer, film, region, plate, or the like, the former may directly contact the latter or still another layer, film, region, plate, or the like may be disposed between the former and the latter. As used herein, when a layer, film, region, plate, or the like is disposed “directly below” or “directly under” another layer, film, region, plate, or the like, the former directly contacts the latter and still another layer, film, region, plate, or the like is not disposed between the former and the latter. Spatially relative terms, such as “beneath,” “below,” “lower,” “lowermost,” “bottom,” “under,” “above,” “upper,” “uppermost,” “top,” and the like, may be used herein for ease of explanation to illustrate one element or feature's relationship to another element or feature as illustrated in the figures. It will be understood that the spatially relative terms are intended to encompass different orientations of the device in use or in operation, in addition to the orientation depicted in the figures. For example, when the device in the drawings may be turned over, elements described as “below” or “beneath” or “under” other elements or features would then be oriented “above” the other elements or features. Thus, the example terms “below” and “under” may encompass both an orientation of above and below. The device may be otherwise oriented, for example, rotated 90 degrees or at other orientations, and the spatially relative descriptors used herein should be interpreted accordingly. It will be understood that when an element or layer is referred to as being “connected to”, or “coupled to” another element or layer, it may be directly on, connected to, or coupled to the other element or layer, or one or more intervening elements or layers may be present. In contrast, when an element is referred to as being “directly coupled,” “directly connected,” or “directly responsive” to, or “directly on,” another element, there are no intervening elements present. In addition, “electrical connection” conceptually includes a physical connection and a physical disconnection. For example, an “electrical connection” between element A and element B may include a direct physical connection between element A and element B and/or an indirect physical connection between element A and element B with one or more intervening elements therebetween.

In addition, unless explicitly described to the contrary, the word “comprise”, and variations such as “comprises” or “comprising”, will be understood to imply the inclusion of stated elements but not the exclusion of any other elements.

Further, in the specification, the phrase “in a plane (plan) view” or “on a plane (plan)” means when an element of a portion is viewed from above, and the phrase “in a cross-sectional view” or “on a cross-section” means when a cross-section taken by vertically cutting an element or a portion is viewed from the side.

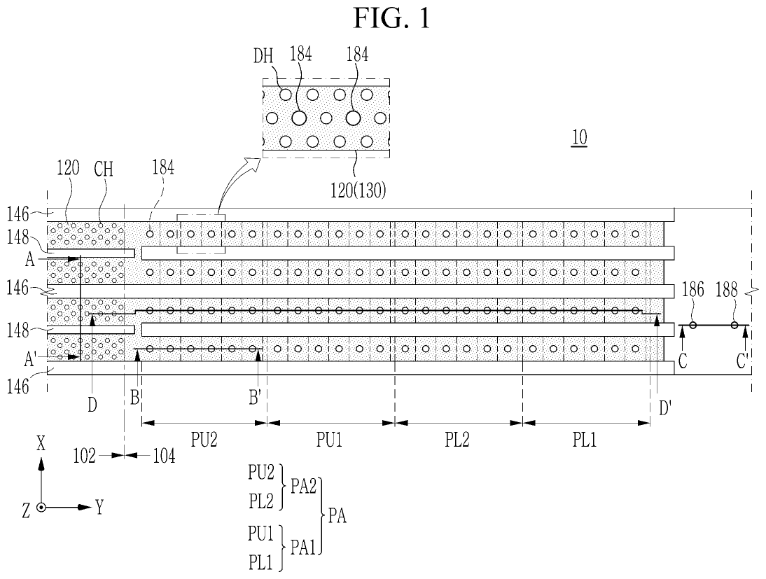

Hereinafter, a semiconductor device and a manufacturing method thereof according to some embodiments are described with reference to FIGS. 1 to 5, FIGS. 6A and 6B, FIGS. 7A and 7B, and FIGS. 8A, 8B, 8C, 8D, 8E, 8F, 8G, 8H, and 8I.

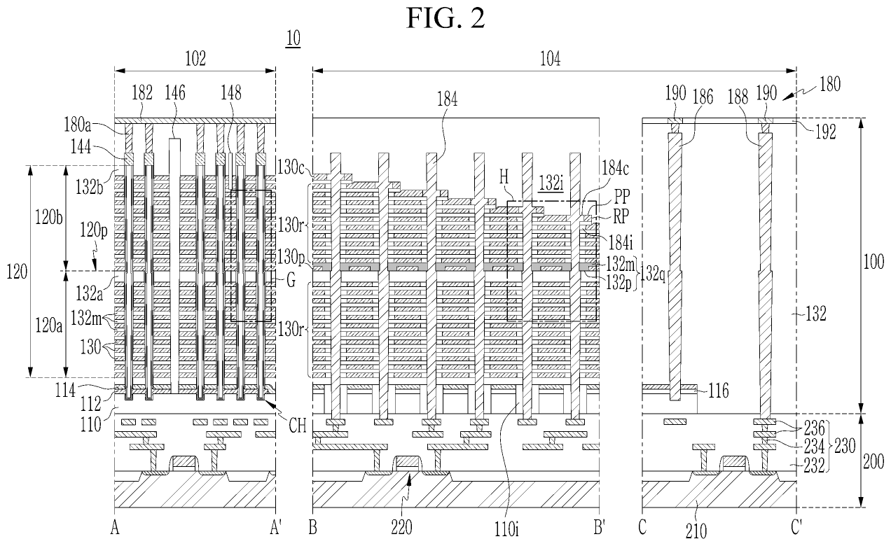

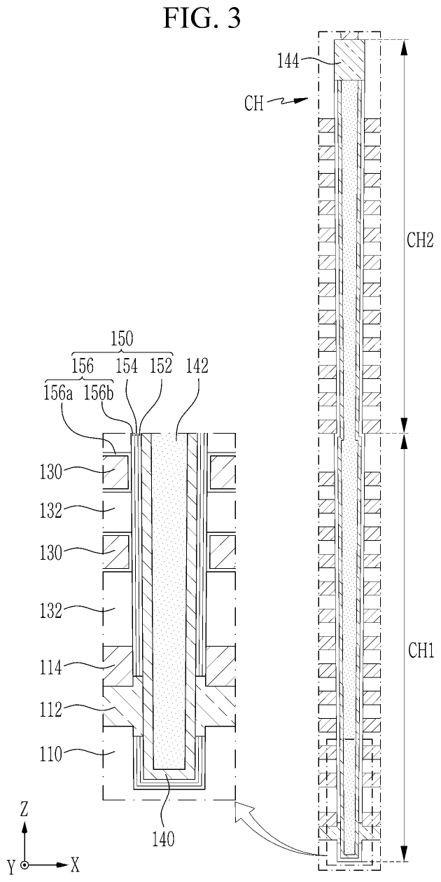

FIG. 1 illustrates a partial plan view of a semiconductor device according to some embodiments. FIG. 2 illustrates partial cross-sectional views of the semiconductor device of FIG. 1 taken along lines A-A′, B-B′, and C-C′. FIG. 3 illustrates partial cross-sectional views of a channel structure included in the semiconductor device shown in FIG. 1 according to some embodiments.

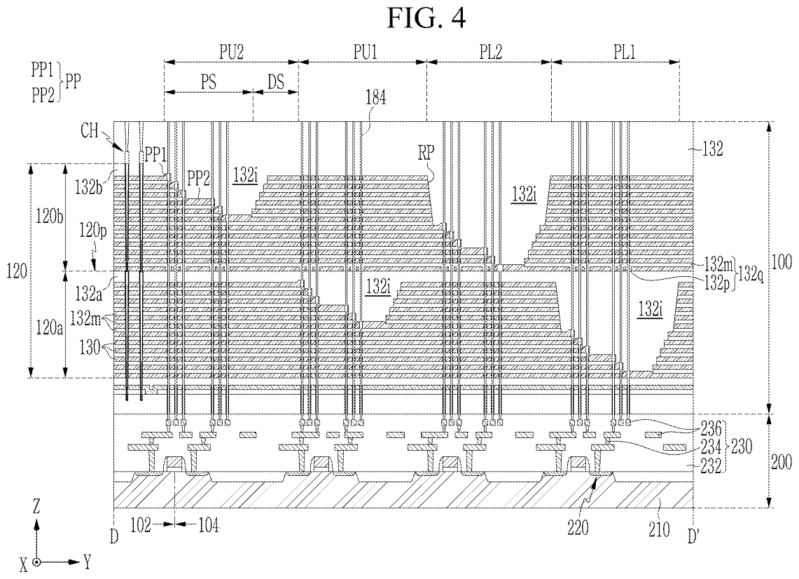

For brief illustration and clear understanding, in FIG. 1, the illustration of the second wire part 180 may be partially omitted, and a channel structure CH and a gate contact portion 184 may be mainly shown. An area disposed between two consecutively positioned dotted lines in FIG. 1 may include a dummy area (reference number DS in FIG. 4) of each pad area PA. Also, for the sake of simplicity, the dummy structure DH may be shown only in the enlarged plan view. For a brief illustration, in drawings other than FIG. 4, an interval between the plurality of gate contact portions 184 may be shown as the same.

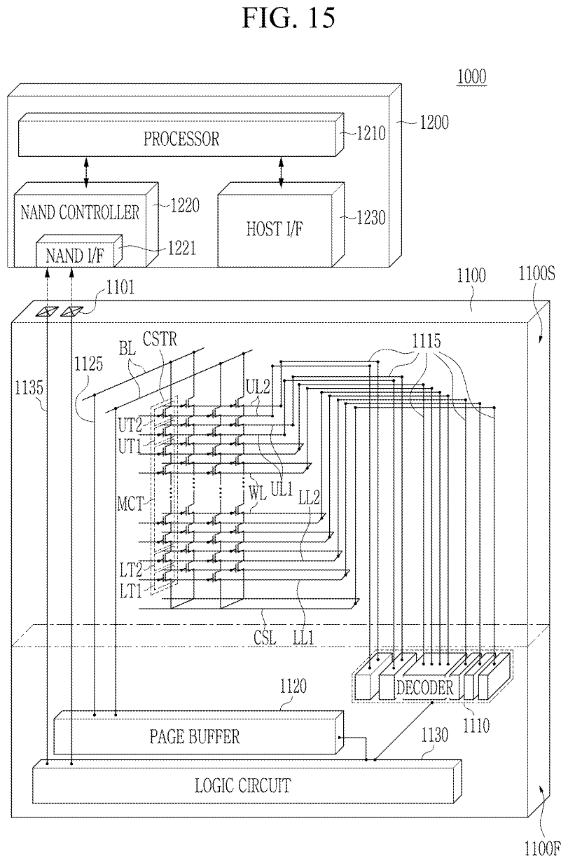

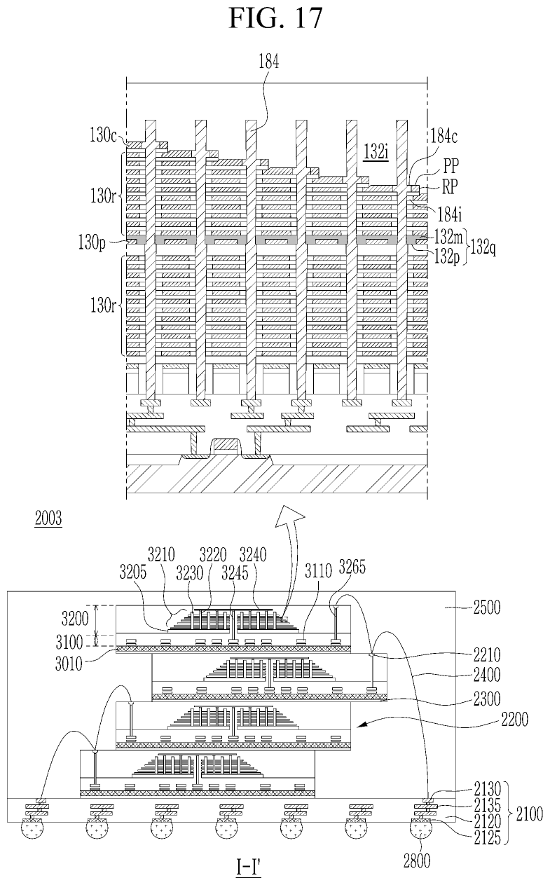

Referring to FIGS. 1 to 3, the semiconductor device 10 according to some embodiments may include a cell area 100 where a memory cell structure is provided and a circuit area 200 where a peripheral circuit structure of controlling the operation of the memory cell structure is provided. For example, the circuit area 200 and the cell area 100 may be parts corresponding to a first structure 1100F and a second structure 1100S of the semiconductor device 1100 included in the electronic system 1000 shown in FIG. 15. In some embodiments, the circuit area 200 and the cell area 100 may include the first structure 3100 and the second structure 3200 of the semiconductor chip 2200 shown in FIG. 17, respectively.

Here, the circuit area 200 may include a peripheral circuit structure formed on the first substrate 210, and the cell area 100 may include a memory cell structure that includes a gate stacking structure 120 and a channel structure CH formed in the cell array area 102 on the second substrate 110. A first wire part 230 may be provided in the circuit area 200, and a second wire part 180 electrically connected to the memory cell structure may be provided in the cell area 100.

In some embodiments, the cell area 100 may be positioned on the circuit area 200. Accordingly, since it is not necessary to secure an area corresponding to the circuit area 200 separately from the cell area 100, the area of the semiconductor device 10 may be reduced. However, the embodiment of the present inventive concept is not limited thereto, and the circuit area 200 may be positioned adjacent (e.g., next to) the cell area 100. Numerous other variations are possible.

The circuit area 200 may include a first substrate 210, and a circuit element 220 and a first wire part 230 formed on the first substrate 210.

The first substrate 210 may be a semiconductor substrate including a semiconductor material. For example, the first substrate 210 may be a semiconductor substrate formed of a semiconductor material or a semiconductor substrate including a semiconductor layer formed on a base substrate. As an example, the first substrate 210 may include a single crystal or polysilicon silicon, epitaxial silicon, germanium, silicon-germanium, silicon-on-insulator (SOI), and/or germanium-on-insulator (GOI), but is not limited thereto.

The circuit element 220 formed on the first substrate 210 may include any of various circuit elements that control the operation of the memory cell structure provided in the cell area 100. For example, the circuit element 220 may include a peripheral circuit structure such as a decoder circuit (reference numeral 1110 in FIG. 15), a page buffer (reference numeral 1120 in FIG. 15), and/or a logic circuit (reference numeral 1130 in FIG. 15), but is not limited thereto.

The circuit element 220 may include, for example, a transistor, but is not limited thereto. For example, the circuit element 220 (e.g., peripheral circuit structure) may include not only an active element, such as a transistor, but also a passive element, such as a capacitor, a resistor, and an inductor.

The first wire part 230 positioned on the first substrate 210 may be electrically connected to the circuit element 220. In some embodiments, the first wire part 230 may include a plurality of wiring layers 236 spaced apart with a first insulation layer 232 therebetween and connected by a contact via 234 to form a desired path. The plurality of wiring layers 236 and the contact via 234 may include a conductive material, and the first insulation layer 232 may include an insulating material. For example, among the plurality of wiring layers 236, the wiring layer 236 positioned at the uppermost portion adjacent to the cell area 100 may have a pad portion to which the gate contact portion 184 and the through plug 188 are connected, or may constitute a pad portion.

The cell area 100 may include a cell array area 102 and a connection area 104. The connection area 104 may be adjacent to the cell array area 102. In the cell array area 102, a gate stacking structure 120 and a channel structure CH may be formed on the second substrate 110. In the cell array area 102 and/or the connection area 104, a structure for connecting the gate stacking structure 120 and/or the channel structure CH formed in the cell array area 102 to the circuit area 200 or an external circuit may be positioned. As used hereinafter, the terms “external/outside configuration”, “external/outside device”, “external/outside power”, “external/outside signal”, or “outside” are intended to broadly refer to a device, circuit, block, module, power, and/or signal that resides externally (e.g., outside of a functional or physical boundary) with respect to a given circuit, block, module, system, or device.

In some embodiment, the second substrate 110 may include a semiconductor layer including a semiconductor material. For example, the second substrate 110 may include a semiconductor layer formed of a semiconductor material or may include a semiconductor layer positioned on the base substrate. For example, the second substrate 110 may be formed of silicon, germanium, silicon-germanium, silicon-on-insulator, or germanium-on-insulator, but is not limited thereto. Here, the semiconductor layer included in the second substrate 110 may be doped with a P-type or N-type impurity. For example, the semiconductor layer in the second substrate 110 may be doped with an N-type impurity (e.g., phosphorus (P), arsenic (As), etc.). However, the embodiments of the present inventive concept are not limited thereto. A substrate insulating portion 110i may be provided in an area through which the gate contact portion 184 extends (e.g., passes) in the second substrate 110. However, the embodiments of the present inventive concept are not limited to the material of the second substrate 110 or the conductivity type and material of the impurity doped on the semiconductor layer of the second substrate 110.

In the cell array area 102, a gate stacking structure 120 including a plurality of cell insulation layers 132 and a plurality of gate electrodes 130 alternately stacked on one surface (e.g., the front surface or the upper surface) of the second substrate 110 and the channel structure CH extending through (e.g., penetrating) the gate stacking structure 120 and at least a portion of the second substrate 110 in a direction perpendicular to the upper surface of the second substrate 110 (e.g., a vertical direction to upper surface of the second substrate 110) may be positioned.

In some embodiments, first and second horizontal conductive layers 112 and 114 may be provided between the second substrate 110 and the gate stacking structure 120 in the cell array area 102. The first and second horizontal conductive layers 112 and 114 may serve to electrically connect the channel structure CH and the second substrate 110. For example, first and second horizontal conductive layers 112 and 114 may include a first horizontal conductive layer 112 positioned on one surface of the second substrate 110, and may further include a second horizontal conductive layer 114 positioned on the first horizontal conductive layer 112. In an area of the connection area 104, the first horizontal conductive layer 112 may not be provided, and the horizontal insulation layer 116 may be provided between the second substrate 110 and the gate stacking structure 120. In the manufacturing process, a part of the horizontal insulation layer 116 (e.g., a part of the horizontal insulation layer 116 in the cell array area 102) may be replaced with the first horizontal conductive layer 112, and another part of the horizontal insulation layer 116 positioned in the connection area 104 may remain.

The first horizontal conductive layer 112 may function as a part of a common source line of the semiconductor device 10. For example, the first horizontal conductive layer 112 along with the second substrate 110 may function as a common source line. As shown in the enlarged view of FIG. 3, the channel structure CH may extend through the first and second horizontal conductive layers 112 and 114 to reach the second substrate 110, and the gate dielectric layer 150 may be removed on a portion (e.g., the gate dielectric layer 150 may expose a portion of the channel layer 140) where the first horizontal conductive layer 112 is positioned so that the first horizontal conductive layer 112 may be connected (e.g., directly connected) to the channel layer 140 (e.g., the circumference of the channel layer 140). It will be understood that when an element A is referred to as exposing another element B, while the element A may be on the element B, the element A may not entirely cover the element B and at least a portion of the element B may not be covered by the element A.

The first and second horizontal conductive layers 112 and 114 may include a semiconductor material (e.g., polysilicon). For example, the first horizontal conductive layer 112 may be an impurity doped polysilicon layer, and the second horizontal conductive layer 114 may be an impurity doped polysilicon layer or a layer including an impurity diffused from the first horizontal conductive layer 112. However, the embodiment of the present inventive concept is not limited thereto, and the second horizontal conductive layer 114 may be formed of an insulating material. Alternatively, the second horizontal conductive layer 114 may not be provided separately.

The gate stacking structure 120 in which the plurality of cell insulation layers 132 and the plurality of gate electrodes 130 are alternately stacked may be positioned on the second substrate 110 (for example, on the first and second horizontal conductive layers 112 and 114 formed on the second substrate 110).

In some embodiments, the gate stacking structure 120 may include a plurality of sub-gate stacking structures (e.g., first and second gate stacking structures 120a and 120b) sequentially stacked on the second substrate 110. Then, since the number of stacked gate electrodes 130 can be increased, the number of the memory cells may be increased. For example, the gate stacking structure 120 may include the first and second gate stacking structures 120a and 120b, thereby increasing the data storage capacity and simplifying the structure. However, the embodiment of the present inventive concept is not limited thereto, and the gate stacking structure 120 may include three or more sub-gate stacking structures.

In the gate stacking structure 120, the plurality of gate electrodes 130 may include a lower gate electrode, a memory cell gate electrode, and an upper gate electrode sequentially positioned on the second substrate 110. The lower gate electrode may be used as a gate electrode of a ground selection transistor, the memory cell gate electrode may constitute the memory cell, and the upper gate electrode may be used as a gate electrode of a string selection transistor. The number of memory cell gate electrodes may be determined according to the data storage capacity of the semiconductor device 10. According to some embodiments, one or two or more lower gate electrodes and upper gate electrodes may be provided, and they may have the same structure as the memory cell gate electrode or a different structure from the memory cell gate electrode. Also, a portion of the gate electrode 130, for example, the memory cell gate electrode adjacent to the lower gate electrode and/or the upper gate electrode may be a dummy gate electrode.

The plurality of cell insulation layers 132 may include an interlayer insulating layer 132m positioned between two adjacent gate electrodes 130 in the first and second gate stacking structures 120a and 120b, and upper insulation layers (e.g., first and second upper insulation layers) 132a and 132b positioned at the upper ends of the first and second gate stacking structures 120a and 120b, respectively. Also, it may further include a pad insulating portion 132i formed in (e.g., filling) the recessed part RP provided in the pad area PA. It will be understood that when element A is referred to as “filling” element B, element A may partially or entirely fill element B. The pad insulating portion 132i may be formed as a part of the first and second upper insulation layers 132a and 132b or may be provided separately from the first and second upper insulation layers 132a and 132b.

For example, the first and second upper insulation layers 132a and 132b may include first and second upper insulation layers 132a and 132b respectively positioned at the upper ends of the first and second gate stacking structures 120a and 120b. The first upper insulation layer 132a may be an intermediate insulation layer separating (e.g., insulating) the first gate stacking structure 120a from the second gate stacking structures 120b, and the second upper insulation layer 132b may be an uppermost insulation layer positioned at the upper end of the gate stacking structure 120. The second upper insulation layer 132b may form a part or all of the cell area insulation layer positioned as a whole at an upper portion of the cell area 100.

In the example embodiment, the thicknesses of the plurality of cell insulation layers 132 may not all be the same. For example, the thicknesses of the first and second upper insulation layers 132a and 132b may be greater than the thickness of the interlayer insulating layer 132m. However, the shape and structure of the cell insulation layer 132 may be variously modified according to embodiments.

For a brief illustration, in FIG. 2, the cell insulation layer 132 may be provided, as a unitary structure without a boundary, on a source contact part 186 and a through plug 188 in the connection area 104. However, the embodiment of the present inventive concept is not limited thereto, and the cell insulation layer 132 in the connection area 104 may include a plurality of insulation layers.

The gate electrode 130 may include a conductive material. For example, the gate electrode 130 may include a metallic material, such as tungsten (W), copper (Cu), and aluminum (Al), polysilicon, a metal nitride, such as titanium nitride (TiN), tantalum nitride (TaN), etc., and/or a combination thereof. As shown in the enlarged view in FIG. 3, a portion (e.g., a first blocking layer 156a) of a blocking layer 156 made of an insulating material may extend around (e.g., surround) gate electrode 130. The cell insulation layer 132 may include an insulating material. For example, the cell insulation layer 132 may include silicon oxide, silicon nitride, silicon oxynitride, a low dielectric constant (low-k) material with a smaller dielectric constant than silicon oxide, and/or a combination thereof.

In some embodiments, a channel structure CH may extend through the gate stacking structure 120 and at least a portion of the second substrate 110 in a direction (for example, a vertical direction perpendicular to an upper surface of the second substrate 110) (e.g., Z-axis direction of the drawing).

The channel structure CH may include a channel layer 140. The channel layer 140 may have, for example, a column shape (e.g., a cylinder shape in a cross-sectional view, a polygonal column shape in a cross-sectional view, and/or annular shape in a plan view). The channel structure CH may include a gate dielectric layer 150 on the channel layer 140 (e.g., on outer side surfaces and/or an outer lower surface of the channel layer 140). The gate dielectric layer 150 may be disposed between the gate electrode 130 and the channel layer 140. The channel structure CH may further include a core insulation layer 142 positioned inside the channel layer 140. For example, when the channel layer 140 is a cylinder shape in a cross-sectional view (e.g., annular shape in a plan view), the core insulation layer 142 may be disposed on inner side surfaces and/or an inner lower surface of the channel layer 140. The channel structure CH may further include a channel pad 144 disposed on the channel layer 140 and/or the gate dielectric layer 150 (e.g., on upper surfaces of the channel layer 140 and/or the gate dielectric layer 150).

Each of a plurality of channel structures CH may include a memory cell string. The plurality of channel structures CH may be spaced apart from each other to form rows and columns on a plane. For example, a plurality of channel structures CH on a plane may be disposed in any of various forms such as a lattice form and a zigzag form. The channel structure CH may have a column shape. For example, when viewed in cross-section, the channel structure CH may have an inclined side surface so that the width of the channel structure CH becomes narrower as it approaches the second substrate 110 according to an aspect ratio. However, the embodiment of the present inventive concept is not limited thereto, and the arrangement, structure, and shape of the channel structure CH may be variously modified.

A core insulation layer 142 may be provided in the central area of the channel structure CH, and the channel layer 140 may extend around (e.g., at least partially cover) an outer side surface and an outer lower surface of the core insulation layer 142. For example, the core insulation layer 142 may have a column shape (e.g., a cylinder shape or a polygonal column shape), and the channel layer 140 may have an annular shape in a plan view. However, the embodiment of the present inventive concept is not limited thereto. For example, the core insulation layer 142 may not be provided and the channel layer 140 may have a column shape (e.g., a cylinder shape in a cross-sectional view or a polygonal column shape in a cross-sectional view).

The channel layer 140 may include a semiconductor material, for example, polysilicon. The core insulation layer 142 may include an insulating material. For example, the core insulation layer 142 may include silicon oxide, silicon nitride, silicon oxynitride, or combination thereof. However, the embodiment of the present inventive concept is not limited to the material of the channel layer 140 and the core insulation layer 142.

The gate dielectric layer 150 positioned between the gate electrode 130 and the channel layer 140 may include a tunneling layer 152, a charge storage layer 154, and a blocking layer 156 sequentially formed on the channel layer 140 (e.g., on an outer side surface and/or an outer lower surface of the channel layer 140).

In this case, the tunneling layer 152 may be a layer through which the charge is tunneled according to the voltage applied to the gate electrode 130 and may include an insulating material capable of tunneling the charge. The tunneling layer 152 may include a material such as silicon oxide or silicon oxynitride, but is not limited thereto. For example, the tunneling layer 152 may be formed by stacking a silicon oxide layer and a silicon nitride layer.

The charge storage layer 154 disposed between the tunneling layer 152 and the blocking layer 156 may be used as a data storage area. For example, the charge storage layer 154 may include silicon nitride capable of trapping charges, and may be made of, for example, silicon nitride. When the charge storage layer 154 is made of silicon nitride, it may have excellent storage stability (retention) and may be advantageous for integration compared to those made of polysilicon. However, the embodiment of the present inventive concept is not limited to the material of the charge storage layer 154.

The blocking layer 156 may be disposed between the charge storage layer 154 and the gate electrode 130. The blocking layer 156 may include an insulating material capable of preventing the charge from undesirably inflowing into the gate electrode 130. For example, the blocking layer 156 may include a silicon oxide, a silicon nitride, a silicon oxynitride, a high dielectric constant material, or a combination thereof, but is not limited thereto. Here, the high dielectric constant material means a dielectric material having a higher dielectric constant than silicon oxide. The high dielectric constant material, for example, may include aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), praseodymium oxide (Pr₂O₃), or combinations thereof, but is not limited thereto.

In some embodiments, the blocking layer 156 may include a first blocking layer 156a including a portion extending horizontally and/or vertically along the gate electrode 130 and a second blocking layer 156b extending vertically between the first blocking layer 156a and the charge storage layer 154. For example, the first blocking layer 156a may extend around the gate electrode 130.

A channel pad 144 may be disposed on the channel layer 140 and/or the gate dielectric layer 150. The channel pad 144 may be disposed to cover the upper surface of the core insulation layer 142 and be electrically connected to the channel layer 140. Channel pad 144 may include a conductive material, for example, impurity doped polysilicon, but is not limited thereto.

As described above, when the plurality of sub-gate stacking structures (e.g., first and second gate stacking structures 120a and 120b) are provided, the channel structure CH may include a plurality of sub-channel structures (e.g., first and second channel structures CH1 and CH2). The first and second channel structures CH1 and CH2 may extend (e.g., pass) through the first and second gate stacking structures 120a and 120b, respectively.

The first and second channel structures CH1 and CH2 may be connected to each other. Each of the first and second channel structures CH1 and CH2 may have an inclined side surface such that the width becomes narrower closer to the second substrate 110 according to an aspect ratio when viewed cross-section. As shown in FIG. 3, a bent portion due to a difference in the width may be formed in the connection portion of the first channel structure CH1 and the second channel structure CH2. As some examples, the first and second channel structures CH1 and CH2 may have the inclined side surface continuously connected without a bent portion. As such, the embodiment is not limited to the shapes of the first and second channel structures CH1 and CH2.

In FIG. 3, it is illustrated that each of the gate dielectric layers 150, the channel layers 140, and the core insulation layers 142 of the first and second channel structures CH1 and CH2 has an integrally extended structure, respectively. For example, the channel layer 140 in the first channel structure CH1 and the channel layer 140 in the second channel structure CH2 may be connected to each other as an integral structure. The gate dielectric layer 150 in the first channel structure CH1 and the gate dielectric layer 150 in the second channel structure CH2 may be connected to each other as an integral structure. The core insulation layer 142 in the first channel structure CH1 and the core insulation layer 142 in the second channel structure CH2 may be connected to each other as an integral structure. In some embodiments, after forming first and second pass-throughs for the first and second channel structures CH1 and CH2, the gate dielectric layer 150, the channel layer 140, and the core insulation layer 142 may be formed over the entire first and second pass-throughs to form the above-described structure. However, the embodiment of the present inventive concept is not limited thereto. In some embodiments, the gate dielectric layers 150, the channel layers 140, and the core insulation layers 142 of the first and second channel structures CH1 and CH2 may be separately formed and then electrically connected to each other. For example, after forming the first pass-through for the first channel structure CH1, the gate dielectric layer 150, the channel layer 140, and the core insulation layer 142 may be formed in the first pass-through, and after forming the second pass-through for the second channel structure CH2, the gate dielectric layer 150, the channel layer 140, and the core insulation layer 142 may be formed in the second pass-through. Numerous other variations are possible.

In some embodiments, the channel pad 144 may be provided on an upper portion of the channel structure CH (e.g., the second channel structure CH2) provided at an upper portion of the gate stacking structure 120 (e.g., the second gate stacking structure 120b). In some embodiments, the channel pad 144 may be provided on first and second channel structures CH1 and CH2, respectively. In this case, the channel pad 144 of the first channel structure CH1 may be connected to the channel layer 140 of the second channel structure CH2.

In some embodiments, the gate stacking structure 120 may be separated by a separation structure 146 that extends through the gate stacking structure 120 and a least a portion of the second substrate 110 in a direction (for example, a vertical direction to an upper surface of the second substrate 110, Z-axis direction of drawing) and partitioned into a plurality of blocks in a plan view by the separation structure 146.

For example, the separation structure 146 may pass through the gate electrode 130 (e.g., plurality of gate electrodes 130) and the cell insulation layer 132 (e.g., plurality of cell insulation layers 132) and extend to the second substrate 110. In a plan view, a plurality of separation structures 146 may extend in a first direction (e.g., Y-axis direction of the drawing) and be spaced apart from each other with a predetermined interval in the second direction (e.g., X-axis direction of the drawing) that intersects with the first direction. It will be understood that when an element or layer is referred to as crossing or intersecting another element or layer, the elements or layers may respectively extend at the same vertical level or different vertical levels in different directions that intersect each other. Accordingly, in a plan view, the plurality of gate stacking structures 120 that are separated by the plurality of separation structures 146 may each extend in the first direction (e.g., Y-axis direction of the drawing) and spaced apart from each other with the predetermined interval in the second direction (e.g., X-axis direction of the drawing). The gate stacking structure 120 partitioned by the separation structure 146 may constitute one memory cell block. However, the embodiment of the present inventive concept is not limited thereto, and the range of the memory cell block is not limited thereto.

For example, the separation structure 146 may have an inclined side surface having a reduced width toward the second substrate 110 when viewed cross-section due to a high aspect ratio. However, the embodiment of the present inventive concept is not limited thereto, and the side surface of the separation structure 146 may be perpendicular to the upper surface of the second substrate 110. In FIG. 2, when viewed in a cross-section, it was exemplified that the separation structure 146 has the continuous inclined side surface in the first and second gate stacking structures 120a and 120b and does not have a bent portion. However, the embodiment of the present inventive concept is not limited thereto, and the separation structure 146 may have a bent portion at the connection portion of the first and second gate stacking structures 120a and 120b.

The separation structure 146 may include an insulating material. For example, the separation structure 146 may be filled with an insulating material such as silicon oxide, silicon nitride, or silicon oxynitride. However, the embodiment of the present inventive concept is not limited thereto, and the structure, shape, material, etc. of the separation structure 146 may be variously modified.

An upper separation area 148 may be formed at an upper portion of the gate stacking structure 120. In a plan view, the plurality of upper separation areas 148 may extend in the first direction (e.g., Y-axis direction of the drawing) and be spaced apart from each other with a predetermined interval in the second direction (e.g., X-axis direction of the drawing) intersecting with the first direction.

The upper separation area 148 may extend (e.g., pass) through one or a plurality of gate electrodes 130 disposed in an upper portion of the gate stacking structure 120 between the separation structures 146. The upper separation area 148, for example, may separate three gate electrodes 130 (e.g., three uppermost gate electrodes 130) from each other in the second direction (e.g., X-axis direction of the drawing). However, the embodiment of the present inventive concept is not limited to the number of the gate electrodes 130 separated by the upper separation area 148. The upper separation area 148 may include an insulating material. For example, the upper separation area 148 may be filled with an insulating material such as silicon oxide, silicon nitride, and/or silicon oxynitride. However, the embodiment of the present inventive concept is not limited thereto, and the structure, shape, and material of the upper separation area 148 may be variously modified.

A connection area 104 and a second wire part 180 may be provided to connect the gate stacking structure 120 and the channel structure CH formed in the cell array area 102 to the circuit area 200 and/or an external circuit.

Here, the second wire part 180 may include members of electrically connecting the gate electrode 130, the channel structure CH, the first and second horizontal conductive layers 112 and 114, and/or the second substrate 110 to the circuit area 200 and/or the external circuit. For example, the second wire part 180 may include a bit line 182, a gate contact portion 184, a source contact part 186, a through plug 188, and contact vias 180a respectively connected to them, and a connection wire 190 connecting them.

The bit line 182 may be positioned on the cell insulation layer 132 of the gate stacking structure 120 formed in the cell array area 102. The bit line 182 may extend in the second direction (e.g., X-axis direction of the drawing) intersecting (e.g., crossing) a direction (e.g., the first direction, Y-axis direction of the drawing) in which the gate electrode 130 is extended. The bit line 182 may be electrically connected to the channel structure CH, for example, the channel pad 144 through the contact via 180a, for example, the bit line contact via.

The connection area 104 may be disposed adjacent (e.g., around) the cell array area 102, and a part of the second wire part 180 may be positioned therein. The connection area 104 may include a member for the connection of the gate electrode 130, the first and second horizontal conductive layers 112 and 114, the second substrate 110, and/or the circuit area 200. In addition, the connection area 104 may include a portion where an input and output pad and/or an input and output connection wire are formed.

For example, the gate contact portion 184 may extend through (e.g., penetrate) the gate stacking structure 120 to be connected to the gate electrode 130, and extend to the pad part provided in the circuit area 200 to be electrically connected to the circuit area 200. The connection structure of the gate contact portion 184 and the gate electrode 130 will be described in detail later. Also, in the connection area 104, the source contact part 186 may extend (e.g., pass) through the cell insulation layer 132 to be electrically connected to the first and second horizontal conductive layers 112 and 114 and/or the second substrate 110, and the through plug 188 may extend (e.g., pass) through the gate stacking structure 120 or be disposed outside the gate stacking structure 120 to be electrically connect to the first wire part 230 of the circuit area 200.

A dummy structure DH may be formed further in the connection area 104. The dummy structure DH may serve to relieve a stress that may be applied to the gate stacking structure 120. It may have the same or similar structure or shape as the channel structure CH, but it is not electrically connected to the bit line 182. The dummy structure DH may be formed together with the channel structure CH in the same process and composed of the same structure, shape, material, etc., or formed in a separate process from the channel structure CH to have a different structure, shape, material, etc. from the channel structure CH. In some embodiments, the dummy structure DH may have a larger size (e.g., larger width) than the channel structure CH in a plan view. In some embodiments, each dummy structure DH may be a hexagonal shape and positioned inside the gate electrode 130 in a plan view. This is only presented as an example, and the embodiment of the present inventive concept is not limited to the shape, position, dispose, number, etc. of the dummy structure DH. In some embodiments, at least a portion of the dummy structure DH may be positioned over the edge of the gate electrode 130 and formed in contact with the separation structure 146. Numerous other variations are possible.

A connection wire 190 may be positioned in the cell array area 102 and/or the connection area 104. The bit line 182, the source contact part 186, and/or the through plug 188 may be electrically connected to the connection wire 190. For example, the source contact part 186 and/or through plug 188 may be connected to the connection wire 190 through the contact via 180a. In some embodiments, since the contact via 180a and the connection wire 190 connected to the gate contact portion 184 are not provided, design freedom (e.g., design flexibility) of the second wire part 180 may be improved. However, according to some embodiments, the contact via 180a and the connection wire 190 may be connected to the gate contact portion 184.

FIG. 2 illustrates that the connection wire 190 is provided as a single layer positioned on the same plane as the bit line 182 and the second insulation layer 192 is positioned in a part other than the second wire part 180. However, this is only briefly shown for convenience. Accordingly, the connection wire 190 may include a plurality of wiring layers (e.g., multi layers) and further include a contact via for an electrical connection with the bit line 182, the gate contact portion 184, the source contact part 186, and/or the through plug 188.

As above-described, by the second wire part 180 and the first wire part 230, the bit line 182, the gate electrode 130, the first and second horizontal conductive layers 112 and 114, and/or the second substrate 110 connected to the channel structure CH may be electrically connect to the circuit element 220 of the circuit area 200.

In FIG. 2, it is exemplified that each of the gate contact portion 184, the source contact part 186, and/or the through plug 188, in cross-section, may have an inclined side surface so that the widths thereof narrow as they approach the upper surface of the second substrate 110 according to the aspect ratio and a bent portion at the boundary of the first and second gate stacking structures 120a and 120b. However, the embodiment of the present inventive concept is not limited thereto. It is also possible that the source contact part 186 and/or the through plug 188 may not have a bent portion at the boundary between the first and second gate stacking structures 120a and 120b. Numerous other variations are possible.

In some embodiments, at a bottom 120p (e.g., a bottom portion) of an upper structure (e.g., a second gate stacking structure 120b) of the gate stacking structure 120 adjacent to a lower structure (e.g., a first gate stacking structure 120a) of the gate stacking structure 120, a first portion of the gate stacking structure 120 adjacent to the channel structure CH and a second portion of the gate stacking structure 120 adjacent to the gate contact portion 184 may have different structures and/or different materials. For example, at (in) the bottom 120p, a bottom gate electrode 130p may be positioned adjacent to the channel structure CH, and a bottom insulating portion 132p may be positioned adjacent to the gate contact portion 184. In some embodiments, the bottom 120p may be a lower portion of the upper structure (e.g., second gate stacking structure 120b) including a lower (e.g., lowermost) surface of the upper structure (e.g., second gate stacking structure 120b). The lower (e.g., lowermost) surface of the upper structure (e.g., second gate stacking structure 120b) may include a lower surface of the bottom insulating portion 132p and/or a lower surface of the bottom gate electrode 130p. As a result, required properties of the channel structure CH and the gate contact portion 184 may be satisfied. Referring to FIGS. 4, 5, 6A, 6B, 7A, and 7B along with FIG. 2, the connection structure of the gate electrode 130 and the gate contact portion 184, and the structure of the bottom gate electrode 130p and the bottom insulating portion 132p at (in) the bottom 120p are further described in detail.

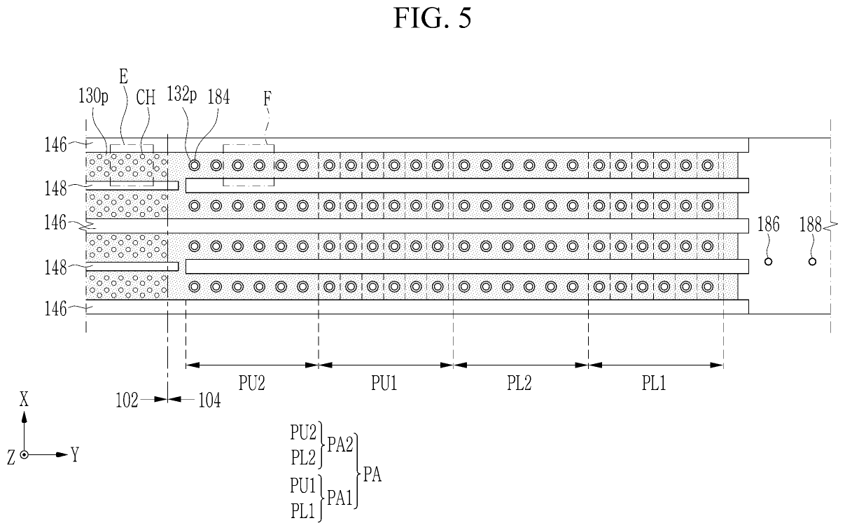

FIG. 4 illustrates a partial cross-sectional view of the semiconductor device 10 of FIG. 1 taken along a line D-D′. FIG. 5 illustrates a partial plan view showing a surface corresponding to an upper surface of the bottom gate electrode 130p in the semiconductor device 10 shown in FIG. 1. For brief illustration and clear understanding, in FIG. 4, the drawing of the second wire part 180 is omitted and the shape of the gate contact portion 184 is schematically shown. Also, FIG. 5 the channel structure CH, the gate contact portion 184, and the like are mainly shown so as to correspond to FIG. 1.

Referring to FIG. 2, FIG. 4, and FIG. 5, in some embodiments, in the connection area 104, the gate electrode 130 and the interlayer insulating layer 132m of the plurality of gate stacking structures (e.g., first and second gate stacking structures 120a and 120b) may be positioned to extend in one direction (e.g., first direction, Y-axis direction of the drawing). A plurality of pad areas PA where the gate contact portion 184 and the gate electrode 130 are connected to each other may be provided in the connection area 104. For example, a plurality of pad areas PA may be provided to electrically connect the plurality of gate electrodes 130 included in the plurality of gate stacking structures (e.g., first and second gate stacking structures 120a and 120b) to the plurality of gate contact portions 184, respectively.

The pad area PA may include a pad zone PS formed by the recessed part RP from which the gate electrode 130 is at least partially removed and a dummy zone DS. The recessed part RP of each pad area PA may include (e.g., filled with) the pad insulating portion 132i.

For example, in the pad zone PS, at least a portion of the plurality of gate electrodes 130 may be sequentially removed by the recessed part RP. In some embodiments, in the pad zone PS, the length of the (remained) plurality of gate electrodes 130 may sequentially increase downward in a direction away from the cell array area 102. For example, the plurality of gate electrodes 130 in the pad zone PS may have a stair shape going downward in a direction away from the cell array area 102. In some embodiments, the plurality of gate electrodes 130 may have a stair shape in one direction or plurality of directions. Accordingly, in the pad zone PS, a plurality of pad portions PP of a plurality of connection gate electrodes 130c may have a shape in which each is exposed upward.

In the dummy zone DS, at least a portion of a plurality of gate electrodes 130 may be sequentially removed by the recessed part RP. In some embodiments, in the dummy zone DS, the length of the plurality of gate electrodes 130 may sequentially increase downward in a direction toward the cell array area 102. For example, in the dummy zone DS, the plurality of gate electrodes 130 may have a stair shape going downward in a direction toward the cell array area 102. The stair shape of the plurality of gate electrodes 130 in the dummy zone DS may have a steeper slope than the stair shape of the plurality of gate electrodes 130 in the pad zone PS, but the embodiment is not limited thereto.

The above-described recessed part RP of the pad area PA may have any shapes or profiles for sequentially exposing the plurality of pad portions PP of the plurality of connection gate electrodes 130c in each pad area PA. The shapes or profiles of the recessed part RP, the gate electrode 130 in the pad zone PS, and the dummy zone DS of each pad area PA may be the same or similar.

In some embodiments, the plurality of pad areas PA may include a first pad area PA1 connected to the gate contact portion 184 in the first gate stacking structure 120a, and a second pad area PA2 connected to the gate contact portion 184 in the second gate stacking structure 120b.

The first and second pad areas PA1 and PA2 may respectively include upper pad areas PU1 and PU2 connected to the gate contact portion 184 at the upper portion of each of the plurality of gate stacking structures (e.g., first and second gate stacking structures 120a and 120b) and lower pad areas PL1 and PL2 connected to the gate contact portion 184 at the lower portion of each of the plurality of gate stacking structures (e.g., first and second gate stacking structures 120a and 120b). In this way, if the upper pad areas PU1 and PU2 and the lower pad areas PL1 and PL2 are formed separately, the forming process of the recessed part RP or the gate electrode 130 having the stair shape in the connection area 104 may be simplified. However, the embodiment of the present inventive concept is not limited thereto, and the number of the pad areas PA included in each of the plurality of gate stacking structures (e.g., first and second gate stacking structures 120a and 120b) may be various.

FIG. 4 illustrates that the second upper pad area PU2, the first upper pad area PU1, the second lower pad area PL2, and the first lower pad area PL1 are sequentially disposed in a direction away from the cell array area 102. However, this is only presented as an example for the explanation, but an embodiment is not limited thereto.

A plurality of gate contact portions 184 may be electrically connected corresponding to the pad portions PP of the plurality of connection gate electrodes 130c exposed through the recessed part RP in each pad area PA.

In some embodiments, each gate contact portion 184 may be electrically connected to the circuit area 200 through the gate stacking structure 120 and the like in the connection area 104. For example, the gate contact portion 184 may be electrically connected to the connection gate electrode 130c having the pad portion PP among a plurality of gate electrodes 130 included in the gate stacking structure 120 and may be electrically insulated from the remaining gate electrodes 130r among the plurality of gate electrodes 130 other than the connection gate electrode 130cby an insulation pattern 184i interposed therebetween.

The pad portion PP may be positioned at the farthest end of the connection gate electrode 130c from the cell array area 102 and may have a larger thickness than other portions of the connection gate electrode 130c. The gate contact portion 184 may be connected to the inner surface of the pad portions PP while extending (e.g., passing) through the pad portions PP of the connection gate electrode 130c in the vertical direction to an upper surface of the second substrate 110 (e.g., Z-axis direction of drawing). For example, the gate contact portion 184 may include a connection portion 184c protruding to the inner surface of the pad portions PP (e.g., in a horizontal direction, X-axis and/or Y-axis directions of drawing) and directly contacting the pad portions PP. The width of the insulating pattern 184i in the horizontal direction (e.g., X-axis and/or Y-axis directions of drawing) may be greater than the thickness of the remaining gate electrodes 130r in the vertical direction or the thickness direction (e.g., Z-axis direction of drawing). According to this, the remaining gate electrode 130r and the gate contact portion 184 may be effectively insulated from each other, but the embodiment of the present inventive concept is not limited thereto.

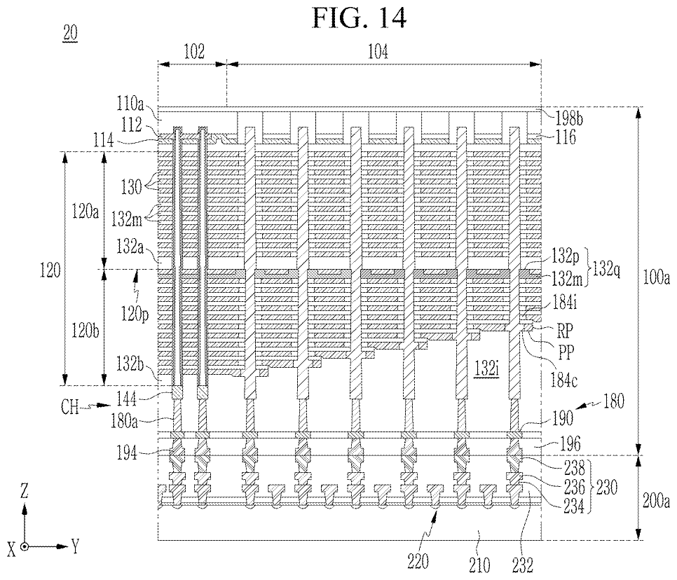

The gate contact portion 184 may extend (e.g., pass) through the gate stacking structure 120, etc., extend to a pad portion provided on the uppermost part of the plurality of wiring layers 236 of the circuit area 200, and be connected to the pad portions PP. As a result, the gate contact portion 184 may be connected to the circuit area 200 without passing through the connection wire 190, etc., and the design freedom (e.g., design flexibility) of the second wire part 180 may be improved. However, a connection method between the gate contact portion 184 and the circuit area 200 may be variously modified. For example, as shown in FIG. 14, the gate contact portion 184 may be connected to a circuit area (reference numeral 200a in FIG. 14) through a connection wire 190 and a second bonding structure 194. This is described in detail with reference to FIG. 14.

The gate contact portion 184 may include a conductive material, for example, tungsten (W), copper (Cu), aluminum (AI), and the like, and may further include a diffusion barrier layer. However, the embodiment of the present inventive concept is not limited to the material of the gate contact portion 184.

Referring to FIG. 4, a plurality of pad portions PP provided in one pad area PA may have a first pad part PP1 having a relatively shorter length and a second pad part PP2 having a relatively longer length. This second pad part PP2 may be formed in consideration of the arrangement of the first wire part 230, the manufacturing process of the semiconductor device 10, and the like. The second pad parts PP2 may be positioned periodically with a plurality of first pad part PP1 interposed therebetween, but is not limited thereto.

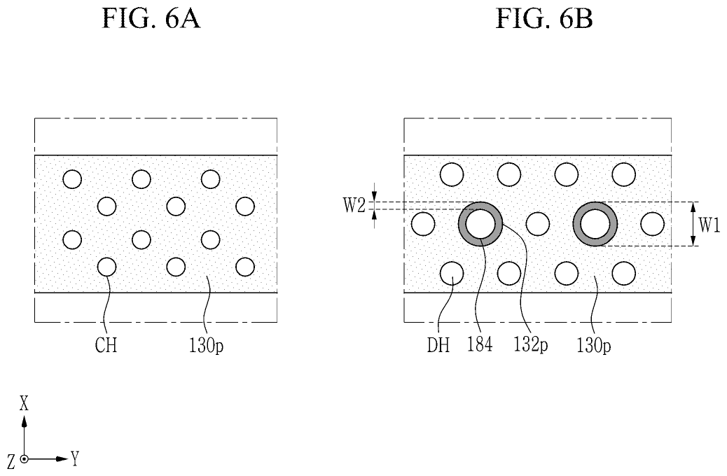

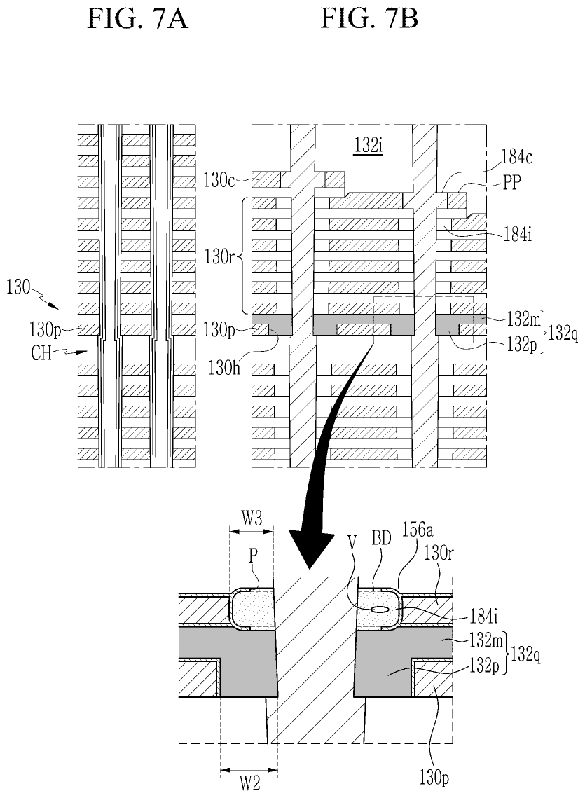

With reference to FIGS. 5, 6A, 6B, 7A, and 7B, the shape of the bottom gate electrode 130p adjacent the channel structure CH and the bottom insulating portion 132p adjacent the gate contact portion 184 at (in) the bottom 120p of the upper structure (e.g., second gate stacking structure 120b) is described in more detail. FIGS. 6A and 6B illustrate enlarged views of a portion E and a portion F of FIG. 5, respectively. FIGS. 7A and 7B illustrate enlarged views of a portion G and a portion H of FIG. 2, respectively.

Referring to FIGS. 5, 6A, 6B, 7A, and 7B, in the bottom 120p of the upper structure (e.g., second gate stacking structure 120b) adjacent to the lower structure (e.g., first gate stacking structure 120a), according to some embodiments, the bottom gate electrode 130p may be positioned adjacent to the channel structure CH, and the bottom insulating portion 132p, which is a separate member from the insulating pattern 184i, may be positioned adjacent to the gate contact portion 184. Here, among the plurality of gate stacking structures (e.g., first and second gate stacking structures 120a and 120b), the gate stacking structure positioned at a lower portion may be referred to as a lower structure, and the gate stacking structure positioned at an upper portion may be referred to as an upper structure. For example, in the first and second gate stacking structures 120a and 120b, the first gate stacking structure 120a may be the lower structure and the second gate stacking structure 120b may be the upper structure.

In the cell array area 102, the channel structure CH (e.g., the side surface of the channel structure CH) may be in contact with the bottom gate electrode 130p. For example, in the bottom 120p of the upper structure, the bottom gate electrode 130p may constitute the lowest layer contacting the lower structure. However, the embodiment of the present inventive concept is not limited thereto, and a layer inevitably formed between the bottom gate electrode 130p, and the lower structure may exist or a separate layer may be further provided.

On the other hand, in the portion adjacent to the gate contact portion 184 in the connection area 104, a gate removed portion 130h in which the bottom gate electrode 130p is partially removed may be provided, and an insulating material may be positioned on the gate removed portion 130h to form a bottom insulating portion 132p. Accordingly, in the bottom 120p, the gate contact portion 184 and the bottom gate electrode 130p among the plurality of remaining gate electrodes 130r may be electrically insulated from each other by the bottom insulating portion 132p interposed therebetween.

For reference, in a portion where the bottom gate electrode 130p constitutes the connection gate electrode 130c in the pad area PA, the bottom insulating portion 132p may not be provided, and the connection portion 184c of the gate contact portion 184 may be electrically connected to the bottom gate electrode 130p. The remaining gate electrodes 130r other than the bottom gate electrode 130p may be insulated from the gate contact portion 184 by the insulating pattern 184i.

As described above, the bottom gate electrode 130p may be provided in the cell array area 102 to increase the number of gate electrodes 130 to increase the number of memory cells and to sufficiently secure a bottom threshold size (a bottom critical dimension, BCD) of the channel structure CH in the bottom 120p (e.g., a bottom area, a bottom diameter, or a bottom width). In addition, the bottom insulating portion 132p may be disposed adjacent to the gate contact portion 184 in the connection area 104 to ensure a sufficient insulating distance between the gate contact portion 184 and the bottom gate electrode 130p. In addition, it is possible to reduce a deviation or a misalignment of the gate contact portion 184 by relatively reducing the bottom threshold size of the gate contact portion 184 in the bottom 120p.

For example, in the upper structure (e.g., second gate stacking structure 120b), the ratio of the lower threshold size of the channel structure CH to the upper threshold size (a top critical dimension, TCD) of the channel structure CH may be larger than the ratio of the lower threshold size of the gate contact portion 184 to the upper threshold size of the gate contact portion 184. Such a difference in the ratio may be due to a difference in the structure or the material in the bottom 120p in the manufacturing process. A more detailed description of this is as follows.

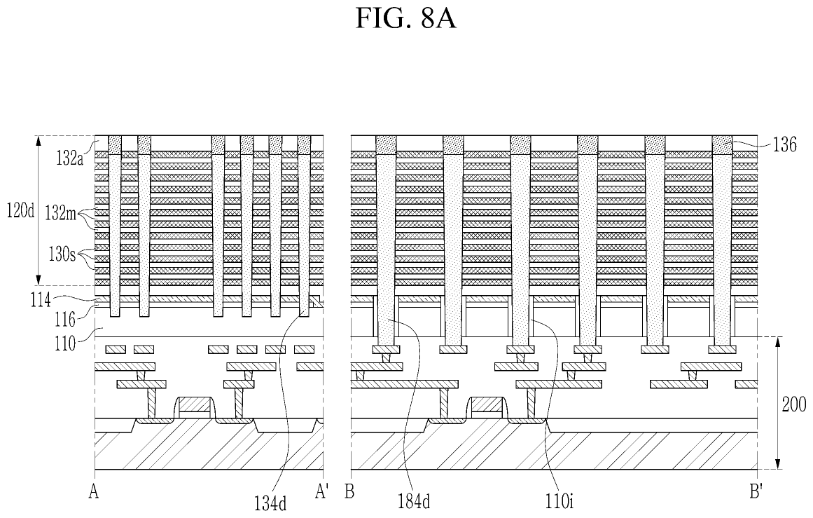

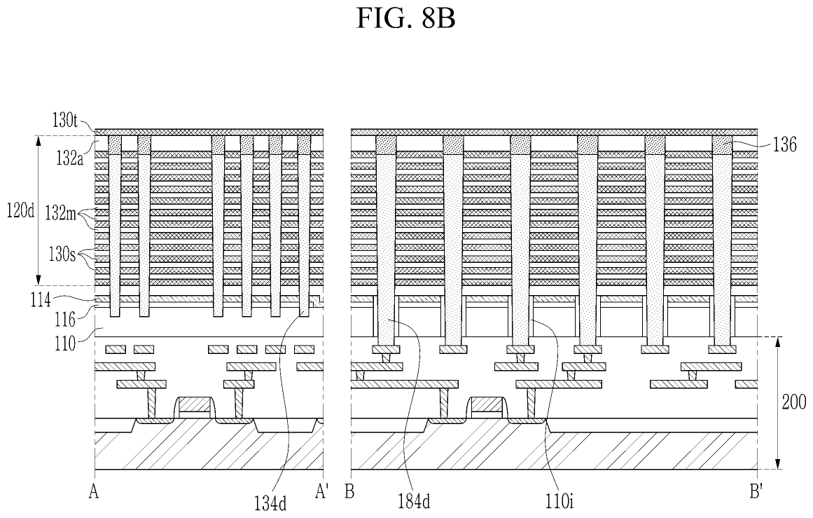

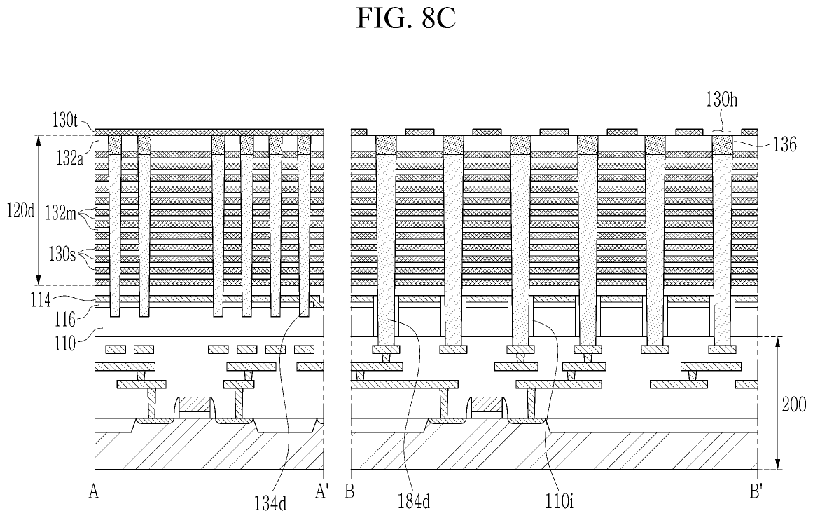

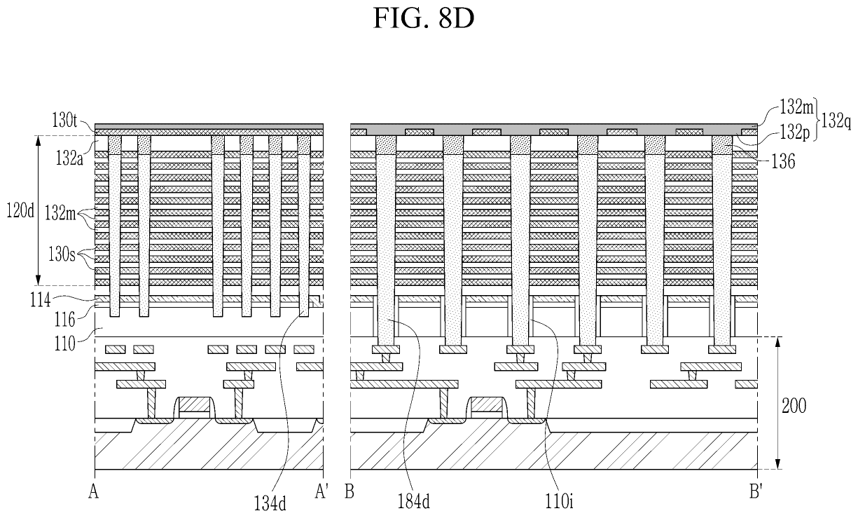

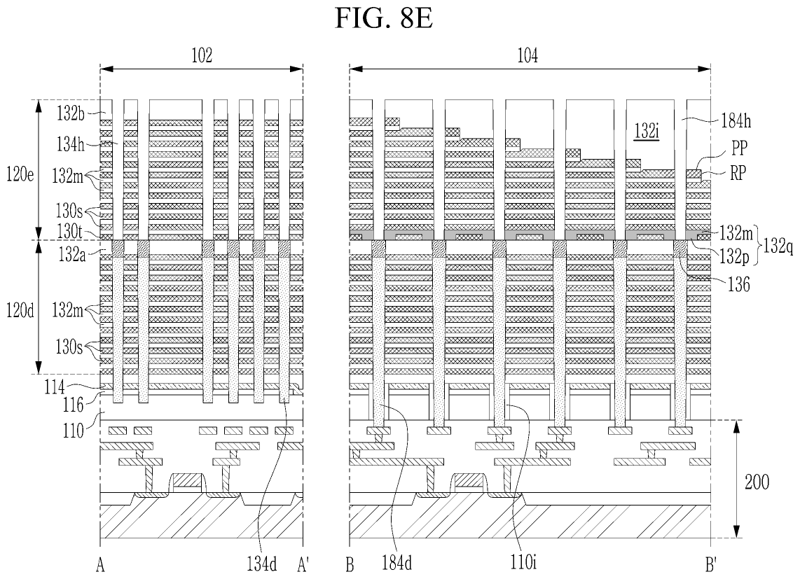

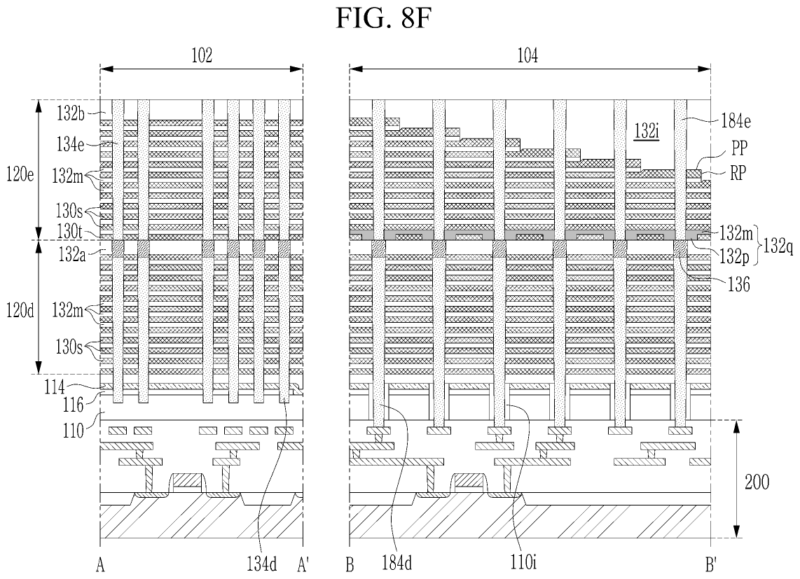

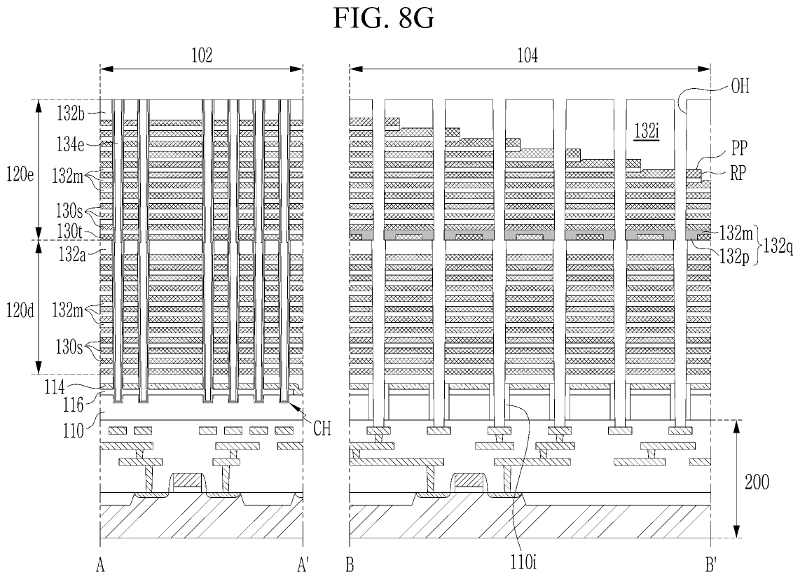

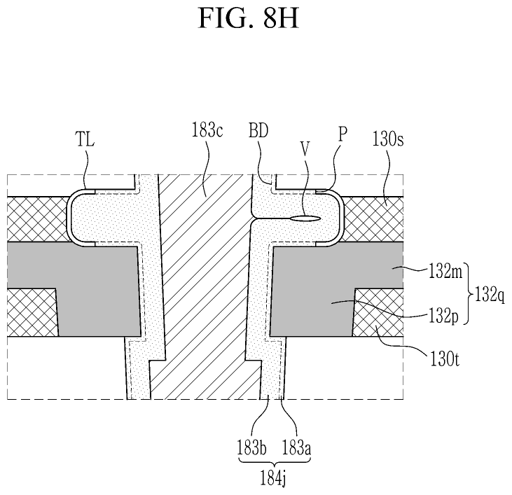

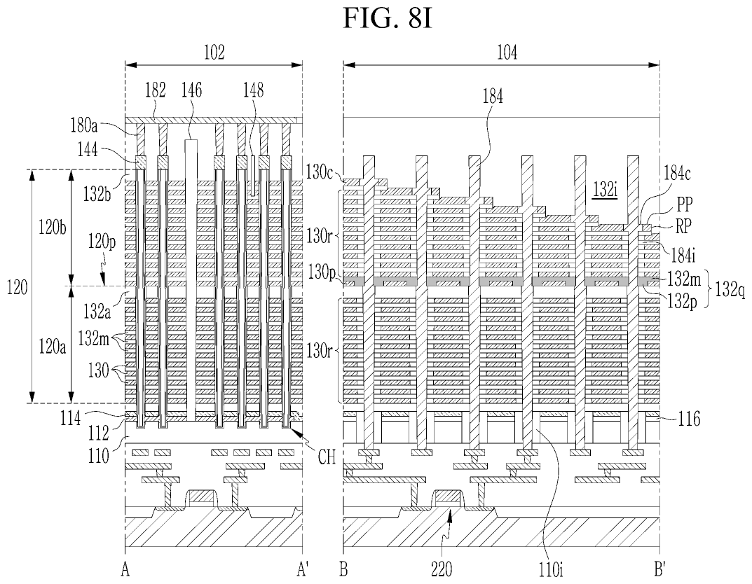

In some embodiments, the gate electrode 130 may be formed by removing a sacrificial insulation layer (reference numerals 130s and 130t in FIG. 8E, hereinafter the same) and filling it with a conductive material.

If the bottom gate electrode 130p is formed adjacent to the channel structure CH in the cell array area 102, when forming a first upper penetration part (reference numeral 134h in FIG. 8E, hereinafter) for the formation of the channel structure CH or the channel sacrificial layer (in further detail, a second channel sacrificial layer (reference numeral 134e in FIG. 8F, hereinafter the same)) in the upper structure, the bottom 120p may include (e.g., may be composed of) a bottom sacrificial insulation layer (reference numeral 130t of FIG. 8E, hereinafter the same). Also, if the bottom insulating portion 132p is formed adjacent to the gate contact portion 184 in the connection area 104, when forming a second upper penetrating portion (reference numeral 184h of FIG. 8E, hereinafter the same) for the formation of the gate contact portion 184 or the wire sacrificial layer (in further detail, a second wire sacrificial layer (reference numeral 184e of FIG. 8F, hereinafter the same)) in the upper structure, the bottom 120p may include (e.g., may be composed of) the bottom insulating portion 132p.

Here, the bottom sacrificial insulation layer 130t may be made of a material that may relatively increase the bottom threshold size during the etching, and the bottom insulating portion 132p may be made of a material that may relatively decrease the bottom threshold size during the etching. In some embodiments, the bottom sacrificial insulation layer 130t may include (e.g., may be made of) nitride (e.g., a silicon nitride), and the bottom insulating portion 132p may include (e.g., may be made of) an oxide (e.g., a silicon oxide). However, the embodiment of the present inventive concept is not limited to the materials of the bottom sacrificial insulation layer 130t and the bottom insulating portion 132p. During the etching to form the first or second upper penetrating portion 134h or 184h, if the lower surface of the second gate stacking structure 120b or the bottom 120p is made of nitride, the bottom threshold size may be relatively larger, and if the lower surface of the second gate stacking structure 120b or the bottom 120p is made of an oxide, the bottom threshold size may be relatively smaller.

In some embodiments, when forming the first and second upper penetrating portions 134h and 184h for the formation of the channel structure CH and the gate contact portion 184, the materials of lower surfaces adjacent the first and second upper penetrating portions 134h and 184h may be different from each other, and then the bottom threshold sizes of the channel structure CH and the gate contact portion 184 may be adjusted as desired.

In some embodiments, when the bottom insulating portion 132p is positioned adjacent to the gate contact portion 184 in the bottom 120p, an insulating distance between the bottom gate electrode 130p and the gate contact portion 184 may be stably secured. For example, it is possible to sufficiently secure a horizontal insulating distance between the bottom gate electrode 130p and the lower portion of the gate contact portion 184 positioned in the upper structure by the bottom insulating portion 132p. In some embodiments, the bent portion positioned on the upper surface of the gate contact portion 184 of the lower structure may be positioned on the same vertical level (e.g., the same plane) as the bottom 120p to ensure the sufficient insulating distance between the upper surface of the gate contact portion 184 of the lower structure and the bottom gate electrode 130p.

In some embodiments, the interlayer insulating layer 132m on (e.g., above) the bottom gate electrode 130p and the bottom insulating portion 132p may have an integrated structure. The interlayer insulating layer 132m on the bottom gate electrode 130p may be one of the interlayer insulating layers 132m. Here, having an integrated structure may mean that two elements are formed together in the same process and formed as a continuous layer having the same material. That is, in the process of forming the interlayer insulating layer 132m on the bottom gate electrode 130p, the bottom insulating portion 132p may be formed together. Here, an insulation layer in which the interlayer insulating layer 132m and the bottom insulating portion 132p are integrated may be referred to as a bottom insulation layer 132q. According to this, a process of filling the insulating material in the gate removed portion 130h may not separately performed, thereby simplifying the process.

In order to distinguish it from other interlayer insulating layers 132m, the bottom insulation layer 132q is displayed in a different color from other interlayer insulating layers 132m in some drawings. This is only for clear understanding, and the bottom insulation layer 132q may have the same material or composition as other interlayer insulating layers 132m.

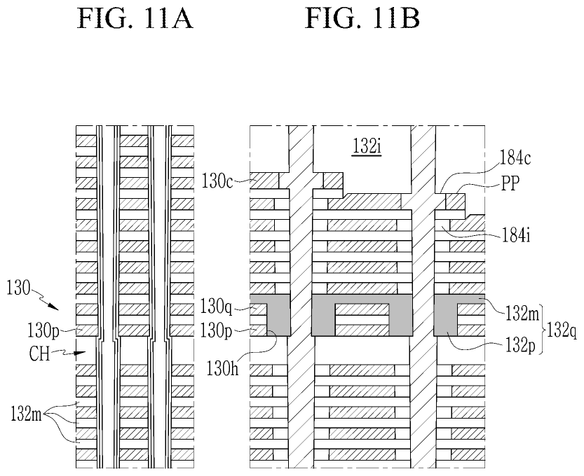

In FIGS. 7A and 7B, it is shown that the gate removed portion 130h is formed on the bottom gate electrode 130p, and the interlayer insulating layer 132m positioned on the bottom gate electrode 130p (e.g., in contact with the bottom gate electrode 130p) constitutes the bottom insulation layer 132q. According to this, the process may be simplified by forming the gate removed portion 130h on the bottom gate electrode 130p, and the bottom insulating portion 132p (e.g., on a side surface of the bottom gate electrode 130p) may be stably formed in the process of forming the interlayer insulating layer 132m (e.g., on an upper surface of the bottom gate electrode 130p). Embodiments different from this will be explained in more detail later with reference to FIG. 11.

The bottom insulating portion 132p may be formed between the bottom gate electrode 130p and the gate contact portion 184 to extend around (e.g., surround) the gate contact portion 184. In this case, when viewed from a plan view, the bottom insulating portion 132p may have a closed shape without cutting the bottom gate electrode 130p and may be partially formed while maintaining an electrical connection passage of the bottom gate electrode 130p. For example, the bottom insulating portion 132p may partially extend around the gate contact portion 184. As a result, the bottom insulating portion 132p may be formed without interfering with the electrical connection passage of the bottom gate electrode 130p.

For example, in the second direction (e.g., X-axis direction of the drawing), the entire width W1 of the bottom insulating portion 132p may be larger than the width of the gate contact portion 184 and smaller than the width of the bottom gate electrode 130p. Here, the entire width W1 of the bottom insulating portion 132p may mean the largest value among the widths of the bottom insulating portion 132p when an outer edge is used as a reference in the width direction of the bottom gate electrode 130p. For example, in a plan view, the entire width W1 of the bottom insulating portion 132p in the second direction at (in) the bottom 120p may include the width (e.g., diameter) of the gate contact portion 184 and two peripheral widths W2 of the bottom insulating portion 132p in the second direction at (in) the bottom 120p. The width of the bottom gate electrode 130p may be defined as the maximum distance among the distances between two neighboring separation structures 146 in the second direction (e.g., X-axis direction of the drawing) or the distance between the edges of both sides of the bottom gate electrode 130p in the second direction. The electrical connection passages may be provided on both sides of the bottom insulating portion 132p by positioning the bottom insulating portion 132p at an inner portion or a central portion of the bottom gate electrode 130p in the width direction of the bottom gate electrode 130p. For example, in a plan view at (in) the bottom 120p, the bottom gate electrode 130p may extend around (e.g., surround) the bottom insulating portion 132p.

For example, the entire width W1 of the bottom insulating portion 132p may be 100 nanometers (nm) to 1000 nm, and the peripheral width W2 of the bottom insulating portion 132p may be 1 nm to 300 nm. Here, the peripheral width W2 of the bottom insulating portion 132p may mean the smallest value among the distances between the outer edge of the gate contact portion 184 and the outer edge of the bottom insulating portion 132p. This is because problems caused by the deviation or misalignment of the gate contact portion 184 may be effectively prevented in this range and the size of the bottom insulating pattern 132p may be prevented from becoming too large. However, the embodiment of the present inventive concept is not limited thereto, and the entire width W1 or the peripheral width W2 of the bottom insulating portion 132p may be variously modified.

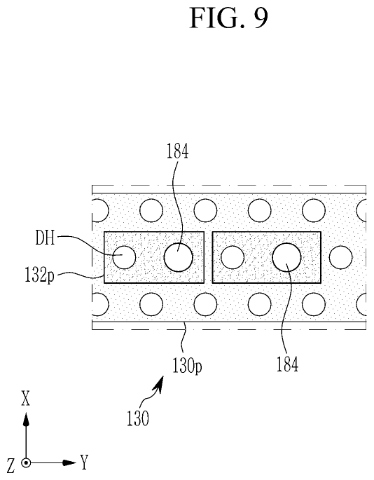

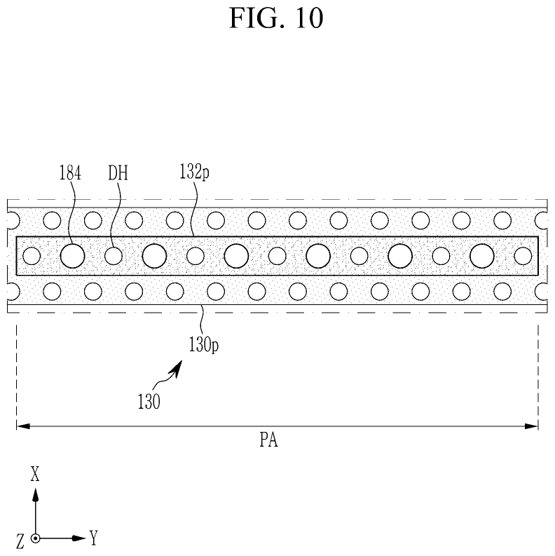

The bottom insulating portion 132p may have a circular shape extending around (e.g., surrounding) one gate contact portion 184 when viewed in a plan view. The bottom insulating portion 132p may have another shape capable of maintaining electrical connection passage, for example, an elliptical shape, a polygon shape, a line shape, and the like. The bottom insulating portion 132p may entirely surround the gate contact portion 184 or may partially extend around the gate contact portion 184. In addition, the shape and arrangement of the bottom insulating portion 132p may be variously modified. Another embodiment of the bottom insulating portion 132p is described with reference to FIG. 9 and FIG. 10 in detail later.

In some embodiments, the bottom insulating portion 132p may be a separate member formed separately from the insulating pattern 184i and may have a structure or material different from that of the insulating pattern 184i. The bottom insulating portion 132p and the insulating pattern 184i may be formed by different methods in different processes. Here, having a different structure may mean that it is formed by different processes and/or different methods and has a difference in, for example, the shape, the stacking structure, and a presence or absence, shape, size of voids, or may include all that are recognized differently due to a difference in at least one of various properties such as shape, stacking structure, presence or absence of voids, shape, size, etc.

In further detail, a tunnel part (reference sign TL of FIG. 8H, hereinafter the same) may be formed by etching the sacrificial insulation layer (e.g., 130s and/or 130t) in the horizontal direction (the direction parallel to the XY plane of the drawing) through the penetrating portion for the wire (reference number OH in FIG. 8G, hereinafter the same) to form the gate contact portion 184, and an insulating pattern 184i may be formed by allowing a portion of a preliminary insulation layer (reference numeral 184j in FIG. 8H, hereinafter the same) formed in the tunnel part (TL) to remain. On the other hand, after forming the bottom sacrificial insulation layer (reference numeral FIG. 8B of 130t, hereinafter the same) for the formation of the bottom gate electrode 130p, the gate removed portion 130h may be formed by etching the bottom gate electrode 130p in the vertical direction (e.g., Z-axis direction in the drawing), and the bottom insulating portion 132p may be formed by filling the gate removed portion 130h with the insulating material. The manufacturing process of the insulating pattern 184i and the bottom insulating portion 132p is described in detail later with reference to FIG. 8A to FIG. 8I.

In some embodiments, the insulating pattern 184i may have a horizontal etching structure etched (e.g., substantially etched) in a horizontal direction and a horizontal filling structure filled (e.g., substantially filled) in a horizontal direction. In some embodiments, the bottom insulating portion 132p may have a vertical etching structure etched (e.g., substantially etched) in a vertical direction and a vertical filling structure filled (e.g., substantially filled) in a vertical direction.

For example, when forming the insulating pattern 184i, since the tunnel part TL is formed by etching in the horizontal direction through the penetrating portion OH for the wire, the side of the insulating pattern 184i may include a convex shape or a rounded portion. For example, as shown in the enlarged view of FIG. 7B, the side of the insulating pattern 184i adjacent to the gate electrode 130 may have a convex shape toward the gate electrode 130. As an example, on a cross-section, since the side surface of the insulating pattern 184i may have an overall convex shape toward the gate electrode 130, the central portion of the side surface of the insulating pattern 184i may protrude most toward the gate electrode 130.

In some embodiments, in the process of forming the bottom insulating portion 132p, the bottom sacrificial insulation layer 130t, which will be replaced with the bottom gate electrode 130p in further processes, may be formed and etched in the vertical direction (e.g., Z-axis direction of the drawing) to form the gate removed portion 130h, so the side surfaces of the bottom insulating portion 132p may be a vertical or inclined surface. The vertical surface may mean a surface perpendicular to the upper surface of the second substrate 110, and the inclined surface may mean an inclined surface having a constant slope and gradually decreasing in width toward the upper surface of the second substrate 110 or the upper surface of the lower structure. In some embodiments, the side surface of the gate removed portion 130h or the bottom insulating portion 132p may have a rounded shape such that the lower portion has a smaller width than the upper portion. As described above, even when the side surface of the gate removed portion 130h or the bottom insulating portion 132p has the rounded shape, the insulating pattern 184i may have a different shape from the convex shape of the insulating pattern 184i.

In some embodiments, the insulating pattern 184i may include a void V extending in a horizontal direction. The void V may be formed because the preliminary insulation layer 184j may partially fill the tunnel part TL when the insulating pattern 184i is formed. In some embodiments, the bottom insulating portion 132p may not include a void. The void may not be formed in the process of forming the bottom insulation layer 132q including the bottom insulating portion 132p because the depth of the gate removed portion 130h may not be deep enough in the vertical direction. Even if the void is formed during the intermediate processes for the bottom insulating portion 132p, the void may be formed in the central portion of the bottom insulating portion 132p and disappear when the penetrating portion OH for the wire is formed. Even when the void remains, since the insulating material (of the bottom insulating portion 132p) is filled in the vertical direction, the void may have a shape extending in the vertical direction.

In some embodiments, the insulating pattern 184i may be formed from the plurality of insulation layers (e.g., the first and second preliminary insulation layers (the reference numerals 183a and 183b of FIG. 8H, hereinafter the same)). Accordingly, the preliminary insulation layer 184j may include boundaries BD among a plurality of insulation layers (e.g., first and second preliminary insulation layers 183a and 183b) having different materials or compositions. In some embodiments, a step P may be formed and/or a portion of the first blocking layer 156a and/or gate electrode 130 may be positioned on the upper surface and/or lower surface of the insulating pattern 184i. In some embodiments, the bottom insulating portion 132p may be formed by one insulating material entirely filling the gate removed portion 130h. Accordingly, the side surface of the bottom insulating portion 132p may be a continuously inclined surface or a vertical surface having a constant slope as a whole and may be composed of a single insulating material. In some embodiments, the bottom insulating portion 132p may have a structure integrated with the interlayer insulating layer 132m as a unitary structure.

For example, after forming the first preliminary insulation layer 183a, including silicon oxynitride and the second preliminary insulation layer 183b, including silicon oxide in the tunnel part TL, an oxidation treatment process may be performed on the first preliminary insulation layer 183a, and a part of the first and second preliminary insulation layers 183a and 183b may remain, thereby forming the insulating pattern 184i. In the oxidation treatment process, a part of the first preliminary insulation layer 183a adjacent to the penetrating portion OH for the wire may be changed to a silicon oxide layer, and a part of the first preliminary insulation layer 183a far from the penetrating portion OH for the wire may not be oxidized and remain as a silicon oxynitride layer. Then, in the process of replacing the sacrificial insulation layers 130s and 130t with the gate electrode 130, when the sacrificial insulation layers 130s and 130t are removed, the remaining unoxidized silicon oxynitride layer from the first preliminary insulation layer 183a may also be removed, so that the first blocking layer 156a and/or a part of the gate electrode 130 may be formed in the corresponding portion. Accordingly, on the upper surface and/or the lower surface of the tunnel part TL, the part of the first preliminary insulation layer 183a, which has been adjacent to the penetrating portion OH for the wire and changed to the silicon oxide layer, remains as a part of the insulating pattern 184i, and the part of the first preliminary insulation layer 183a that is away from the penetrating portion OH for the wire, not oxidized, and remains as the silicon oxynitride layer may be replaced with the first blocking layer 156a and/or the gate electrode 130. As a result, the step P or a part of the first blocking layer 156a and/or the gate electrode 130 may be positioned on the upper surface and/or the lower surface of the insulating pattern 184i.

In some embodiments, the bottom insulating portion 132p or the bottom insulation layer 132q including the bottom insulating portion 132p may be distinguished from the insulating pattern 184i or the cell insulation layer 132 by having a material or composition different from that of the insulating pattern 184i or the cell insulation layer 132. In some embodiments, even when the bottom insulation layer 132q or the bottom insulating portion 132p in the bottom insulation layer 132q has the same material or composition as the insulating pattern 184i or the cell insulation layer 132, the boundary of the bottom insulation layer 132q having the bottom insulating portion 132p may be identified in a transmission micrograph (TEM). From this, the bottom insulating portion 132p or the bottom insulation layer 132q including the bottom insulating portion 132p may be recognized. As the boundary of the bottom insulation layer 132q including the bottom insulating portion 132p is recognized, it can be seen that the bottom insulating portion 132p included in the bottom insulation layer 132q and the interlayer insulating layer 132m (in the bottom insulation layer 132q) may have an integrated structure (e.g., the bottom insulation layer 132q).

In some embodiments, the peripheral width W2 of the bottom insulating portion 132p may be greater than the width W3 of the insulating pattern 184i. Here, the width W3 of the insulating pattern 184i may mean the smallest width among widths (e.g., the smallest distance of the insulating pattern 184i) from one side of the gate contact portion 184. In this way, when the peripheral width W2 of the bottom insulating portion 132p is greater than the width W3 of the insulating pattern 184i, a sufficient insulating distance between the bottom gate electrode 130p and the gate contact portion 184 may be secured. However, the embodiment of the present inventive concept is not limited thereto, and the peripheral width W2 of the bottom insulating portion 132p may be equal to or smaller than the width W3 of the insulating pattern 184i.

As shown in FIG. 4, when the bottom insulating portion 132p is positioned on the bottom 120p of the upper structure in each of the plurality of pad area PAs, the effect of the bottom insulating portion 132p may be increased. In this case, the bottom insulating portion 132p may be formed on the bottom 120p of the upper structure to correspond to all pad area PA regardless of whether the upper structure and the lower structure are an insulating structure or a connection structure. Here, in each pad area PA, the connection structure may mean a gate stacking structure, including the connection gate electrode 130c, and the insulating structure may mean a gate stacking structure without the connection gate electrode 130c.

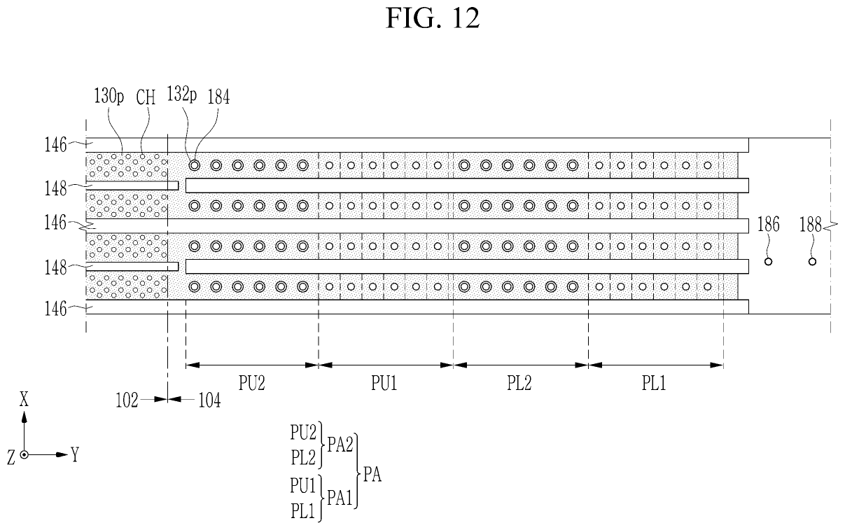

The embodiment of the present inventive concept is not limited thereto, and the bottom insulating portion 132p may be formed to correspond to at least one pad area PA among a plurality of pad areas PA. This is described later in detail with reference to FIG. 12.

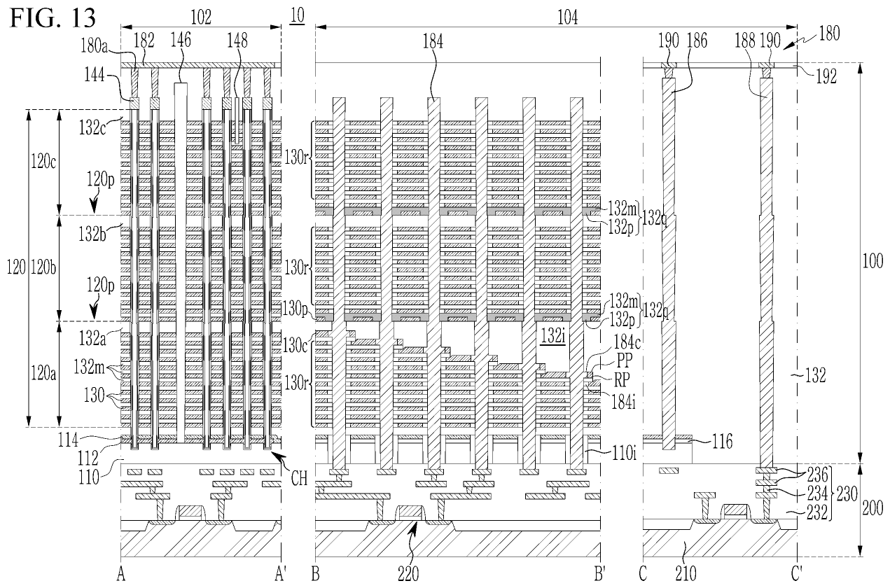

Although not shown in FIG. 4, even when both the upper structure and the lower structure are insulating structures, the bottom insulating portion 132p may be formed on the bottom 120p of the upper structure. This is described later in detail with reference to FIG. 13.

In some embodiments, a plurality of bottom insulating portions 132p may be formed to correspond to a plurality of gate contact portions 184 formed in one pad area PA, respectively. According to this, the bottom insulating portion 132p may be formed in each of the plurality of gate contact portions 184 to increase the effect of the bottom insulating portion 132p. However, the embodiment of the present inventive concept is not limited thereto. Accordingly, the bottom insulating portion 132p may be formed to correspond to at least one of the plurality of gate contact portions 184 positioned within one pad area PA.

According to some embodiments, the portions of the bottom 120p of the upper structure adjacent to the channel structure CH and adjacent to the gate contact portion 184 may have different structures or materials so that required properties of the channel structure CH and the gate contact portion 184 are respectively satisfied. For example, the number of memory cells may be increased, and the channel structure CH may be stably connected for sufficiently secured bottom threshold size of the channel structure CH by positioning the bottom gate electrode 130p at the portion adjacent to the channel structure CH. When the bottom insulating portion 132p is positioned adjacent to the gate contact portion 184, the sufficient insulating distance between the gate contact portion 184 and the bottom gate electrode 130p may be ensured, and problems caused by a deviation or a misalignment of the gate contact portion 184 may be effectively reduced. Accordingly, the reliability and productivity of the semiconductor device 10 may be improved.

On the other hand, if the part adjacent to the channel structure and the gate contact portion has the same bottom structure, at least one of the properties of the channel structure and the gate contact portion may be deteriorated. For example, when the bottom gate electrode is positioned at the bottom in the cell array area and the connection area, it may be difficult to secure a sufficient insulating distance between the gate contact portion and the bottom gate electrode in the connection area. As another example, in order to sufficiently secure the insulating distance between the gate contact portion and the gate electrode, if the insulation layer composed entirely of oxide is positioned in the cell array area and the connection area, since the number of memory cells is reduced and the bottom threshold size of the channel structure is not sufficient, the channel structure may not be connected stably at the bottom.

An example of a manufacturing method for manufacturing the semiconductor device 10 having the above structure is described in detail with reference to FIGS. 8A, 8B, 8C, 8D, 8E, 8F, 8G, 8H, and 8I along with FIGS. 1 to 5, FIGS. 6A and 6B, and FIGS. 7A and 7B. For the parts that have already been explained, the detailed description may be omitted, and the parts not explained in detail are explained.

FIGS. 8A, 8B, 8C, 8D, 8E, 8F, 8G, 8H, and 8I illustrate partial cross-sectional views showing a manufacturing method of a semiconductor device according to some embodiments. FIGS. 8A, 8B, 8C, 8D, 8E, 8F, 8G, and FIG. 8I show the partial cross-section views of the semiconductor device 10 taken along the lines A-A′ and B-B′ of FIG. 1, and FIG. 8H shows a portion corresponding to the enlarged view shown in FIG. 7B. Hereinafter, the manufacturing method of the semiconductor device 10 is described focusing the gate stacking structure 120, the channel structure CH, and the gate contact portion 184 formed in the cell area 100.

As shown in FIG. 8A, on a circuit area 200 including a peripheral circuit structure, a first stacking structure 120d, which is a lower structure, may be formed by alternately stacking a plurality of sacrificial insulation layers 130s and a plurality of interlayer insulating layers 132m. A second substrate 110, a horizontal insulation layer 116, a second horizontal conductive layer 114, and the like may be further formed between the circuit area 200 and the first stacking structure 120d.

Here, the first stacking structure 120d may include the alternately stacked sacrificial insulation layers 130s and interlayer insulating layers 132m, a recessed part RP formed corresponding to the first pad area (reference numeral PA1 in FIG. 1, hereinafter the same), a first upper insulation layer 132a covering them as a whole, and a first channel sacrificial layer 134d and a first wire sacrificial layer 184d penetrating the first stacking structure 120d.

First, the horizontal insulation layer 116 and the second horizontal conductive layer 114 may be formed on the second substrate 110, the interlayer insulating layer 132m and the sacrificial insulation layer 130s may be alternately laminated thereon, and then the first upper insulation layer 132a may be formed. Here, the sacrificial insulation layer 130s may be a layer that is replaced with a gate electrode (reference numeral 130 of FIG. 2, hereinafter the same) through a subsequent process, and at least part of the horizontal insulation layer 116 may be a layer that is replaced with a first horizontal conductive layer through a subsequent process (reference numeral 112 of FIG. 2, hereinafter the same). That is, the sacrificial insulation layer 130s may be formed to correspond to a portion where the gate electrode 130 is to be formed, and the horizontal insulation layer 116 may be formed to include a portion where the first horizontal conductive layer 112 is to be formed.

The horizontal insulation layer 116 and/or the sacrificial insulation layer 130s may be formed of a material different from that of the interlayer insulating layer 132m. For example, the interlayer insulating layer 132m may include silicon oxide, silicon nitride, silicon oxynitride, low dielectric constant (low-k) material, etc., and the sacrificial insulation layer 130s may include silicon, silicon oxide, silicon carbide, silicon nitride, etc. and may be form of a material different from that of the interlayer insulating layer 132m.

Subsequently, a recessed part (reference numeral RP of FIG. 4, hereinafter the same) may be formed to correspond to the first pad area PA1. For example, in the plurality of interlayer insulating layers 132m and the plurality of sacrificial insulation layers 130s, the recessed part RP disposed in the first upper pad area PU1 and the first lower pad area PL1 shown in FIG. 4 may be formed. This recessed part RP may be formed by a sequential etching process using a mask layer. For example, the recessed part RP may be formed by sequentially increasing an exposed area (e.g., plurality of exposed areas) by using a mask layer (e.g., plurality of mask layers) and performing a stepwise etching process (plurality of stepwise etching processes) on the sacrificial insulation layer 130s and the interlayer insulating layer 132m.

Subsequently, the thickness of the sacrificial insulation layer 130s in the pad portion of the gate electrode 130 (reference numeral PP in FIG. 4, hereinafter the same) may be increased from the thickness of the other portions of the sacrificial insulation layer 130s. For example, after forming an additional sacrificial insulation layer, the thickness of the sacrificial insulation layer 130s of the pad portions PP may be increased by patterning such that the additional sacrificial insulation layer remains only on the pad portions PP.

Subsequently, the first upper insulation layer 132a may be formed on (e.g., to entirely cover) the sacrificial insulation layer 130s and the interlayer insulating layer 132m. The pad insulating portion (reference numeral 132i of FIG. 4, hereinafter the same) filling the recessed part RP may be formed before forming the first upper insulation layer 132a separately from the first upper insulation layer 132a or may be formed as a part of the first upper insulation layer 132a.

Subsequently, a first channel sacrificial layer 134d extending through (e.g., penetrating) the first stacking structure 120d may be formed in the cell array area 102, and a first wire sacrificial layer 184d extending through (e.g., penetrating) the first stacking structure 120d may be formed in the connection area 104. The first channel sacrificial layer 134d may be formed to correspond to the first channel structure (reference numeral CH1 of FIG. 3, hereinafter the same), and the first wire sacrificial layer 184d may be formed to correspond to the part of the gate contact portion 184 formed in the first gate stacking structure (reference numeral 120a of FIG. 2, hereinafter the same). The first channel sacrificial layer 134d and/or the first wire sacrificial layer 184d may include an upper sacrificial layer 136 at an upper portion of the first channel sacrificial layer 134d and/or the first wire sacrificial layer 184d.

The first channel sacrificial layer 134d and the first wire sacrificial layer 184d may be formed by depositing a sacrificial material after forming the penetrating portion extending through (e.g., penetrating) the first stacking structure 120d and forming an upper sacrificial layer 136 on the corresponding portion after removing a part of the sacrificial material by an etch-back process. For example, the sacrificial material of the first channel sacrificial layer 134d and/or the first wire sacrificial layer 184d may include polysilicon or tungsten, but is not limited thereto, and the upper sacrificial layer 136 may include titanium nitride (TiN) or the like. The upper sacrificial layer 136 may suppress (e.g., prevent) the bottom threshold size of the first or second upper penetrating portion (reference numerals 134h or 184h in FIG. 8E) from increasing undesirably when the penetrating portion is formed or suppress (e.g., prevent) the sacrificial material of the first wire sacrificial layer 184d or the first channel sacrificial layer 134d from coming out therefrom. However, the embodiment of the present inventive concept is not limited thereto, and it is also possible that the upper sacrificial layer 136 is not provided.

Subsequently, as shown in FIG. 8B, a bottom sacrificial insulation layer 130t for forming a bottom gate electrode (reference numeral 130p of FIG. 8I, hereinafter the same) may be formed on the first stacking structure 120d, which is the lower structure. For example, the bottom sacrificial insulation layer 130t may include a nitride (e.g., a silicon nitride), but is not limited thereto.

The bottom sacrificial insulation layer 130t may be formed by the same type of process or method as the other sacrificial insulation layers 130s, thereby being formed of the same material as the other sacrificial insulation layers 130s. However, the embodiment of the present inventive concept is not limited thereto, and the bottom sacrificial insulation layer 130t may be formed by a process or method different from that of the other sacrificial insulation layer 130s and/or may have a different material or composition.

Next, as shown in FIG. 8C, the bottom sacrificial insulation layer 130t may be partially removed to form a gate removed portion 130h. In further detail, in the connection area 104, the bottom sacrificial insulation layer 130t may be partially removed so as to expose the upper area of the first wire sacrificial layer 184d to form the gate removed portion 130h. That is, the gate removed portion 130h may be formed in an area including a portion where the second upper penetrating portion 184h for forming the gate contact portion 184 is to be formed.

The gate removed portion 130h may have a vertical etching structure formed by etching the bottom sacrificial insulation layer 130t in a vertical direction. Accordingly, the side surface of the gate removed portion 130h may be configured as an inclined surface or a vertical surface. Here, the gate removed portion 130h may be formed by any of various etching processes. For example, the gate removed portion 130h may be formed by a plasma etch process and may be composed of an inclined surface or a vertical surface. In some embodiments, the gate removed portion 130h may be formed by a wet etching and may include an inclined surface, a vertical surface, or a rounded portion such that the width of the lower portion is smaller than that of the upper portion. Since the thickness of the gate removed portion 130h is not large, it can have the inclined or vertical surface even by the wet etching. In some embodiments, by the wet etching, the gate removed portion 130h may have the rounded shape with the smaller lower portion than the upper portion.

Subsequently, as shown in FIG. 8D, while filling the gate removed portion 130h with an insulating material, an interlayer insulating layer 132m and the bottom insulating portion 132p may be formed on the bottom sacrificial insulation layer 130t to form a bottom insulation layer 132q. The bottom insulation layer 132q, thus formed, may have a structure in which the bottom insulating portion 132p and the interlayer insulating layer 132m are integrated. For example, the bottom insulating portion 132p or bottom insulation layer 132q may include an oxide (e.g., a silicon oxide), but are not limited thereto.

The bottom insulation layer 132q may be formed by the same type of process or method as the other interlayer insulating layer 132m and made of the same material as the other interlayer insulating layer 132m. However, the embodiment of the present inventive concept is not limited thereto, and the bottom insulation layer 132q may be formed by a process or method different from that of the other interlayer insulating layer 132m and/or may have a different material or composition.

As shown in FIG. 8E and FIG. 8F, a second stacking structure 120e including a bottom sacrificial insulation layer 130t and a bottom insulation layer 132q may be formed.

Here, the second stacking structure 120e may include sacrificial insulation layers 130s and interlayer insulating layers 132m alternately stacked on the bottom insulation layer 132q, the recessed part RP formed corresponding to the second pad area (reference numeral PA2 of FIG. 1, hereinafter the same), a second upper insulation layer 132b disposed on (e.g., covering) them, a second channel sacrificial layer 134e and a second wire sacrificial layer 184e extending through (e.g., penetrating) the second stacking structure 120e. At this time, the recessed part RP may be formed in a shape provided in the second upper pad area PU2 and the second lower pad area PL2 shown in FIG. 4. Since the descriptions of forming the first stacking structure 120d and sub-structures therein may be applied to the manufacturing process of the sacrificial insulation layer 130s, the interlayer insulating layer 132m, the recessed part RP, and the second upper insulation layer 132b of the second stacking structure 120e, the detailed description may be omitted.

First, as shown in FIG. 8E, after forming the sacrificial insulation layer 130s and the interlayer insulating layer 132m, the recessed part RP, and the second upper insulation layer 132b, a first upper penetrating portion 134h for forming a channel structure CH may be formed in the cell array area 102, and a second upper penetrating portion 184h for forming a gate contact portion 184 may be formed in the connection area 104. The first upper penetrating portion 134h and the second upper penetrating portion 184h may be formed by an etching (e.g., a plasma etch, etc.).

In this case, the bottom sacrificial insulation layer 130t may be positioned at the lower surface of the second stacking structure 120e in the cell array area 102 where the first upper penetrating portion 134h is formed. For example, a lower surface of the bottom sacrificial insulation layer 130t may be a portion of the lower surface of the second stacking structure 120e in the cell array area 102. In this way, when the bottom sacrificial insulation layer 130t includes a nitride (e.g., silicon nitride), the ratio of the lower threshold size to the upper threshold size in the first upper penetrating portion 134h may be relatively large (e.g., larger than that of the second upper penetrating portion 184h). As a result, the lower threshold size of the first upper penetrating portion 134h can have a sufficient size.

In addition, the bottom insulating portion 132p may be positioned at the portion where the lower surface of the first upper penetrating portion 134h is formed in the connection area 104. For example, a lower surface of the bottom insulating portion 132p may be a portion of the lower surface of the second stacking structure 120e in the connection area 104. In this way, when the bottom insulating portion 132p include an oxide (e.g., silicon oxide), the ratio of the lower threshold size to the upper threshold size in the second upper penetrating portion 184h may be relatively small (e.g., smaller than that of the first upper penetrating portion 134h). Accordingly, the second upper penetrating portion 184h for forming the gate contact portion 184 may be stably positioned on the first wire sacrificial layer 184d.

Next, as shown in FIG. 8F, a second channel sacrificial layer 134e and a second wire sacrificial layer 184e may be formed (e.g., deposited) by forming a sacrificial material on (e.g., in) the first upper penetrating portion 134h and the second upper penetrating portion 184h. For example, the second channel sacrificial layer 134e or the second wire sacrificial layer 184e may include polysilicon, tungsten, and the like.

Next, as shown in FIG. 8G to FIG. 8I, the first and second channel sacrificial layers 134d and 134e, the first and second wire sacrificial layers 184d and 184e, the sacrificial insulation layers 130s and 130t may be removed, and a channel structure CH, and a gate contact portion 184 and a gate electrode 130 may be formed.

More specifically, as shown in FIG. 8G, a channel structure CH may be formed, and a penetrating portion OH for a wire may be formed. An upper separation area 148 may be further formed in a part of the second stacking structure 120e. The upper separation area 148 may be formed by forming an upper separation opening by an etching process using a mask layer and depositing an insulating material into the upper separation opening.

That is, the channel structure CH may be formed in the penetrating portion formed by removing the first and second channel sacrificial layers (reference numerals 134d and 134e in FIG. 8F). For example, to form a channel structure CH, a gate dielectric layer (reference numeral 150 in FIG. 3, hereinafter the same), a channel layer (reference numeral 140 in FIG. 3, hereinafter the same), a core insulation layer (reference numeral 142 in FIG. 3, hereinafter the same) sequentially formed to fill the penetrating portion, and a channel pad (reference numeral 144 of FIG. 3, hereinafter the same) may be formed on the channel layer 140. At this time, the first blocking layer (reference numeral 156a of FIG. 3, hereinafter the same) of the gate dielectric layer 150 may be not formed and may be formed later in another process.

Also, a penetrating portion OH for a wire may be formed by removing the first and second wire sacrificial layers (reference numerals 184d and 184e in FIG. 8G). Before forming the penetrating portion OH for the wire, a part of the cell insulation layer 132 covering the channel structure CH may be further formed. The penetrating portion OH for the wire may extend through (e.g., penetrate) the first and second stacking structures 120d and 120e and the substrate insulating portion 110i of the second substrate 110 to reach the circuit area 200. The penetrating portion OH for the wire may be formed to expose a pad portion of the circuit area 200.

Subsequently, as shown in FIG. 8H, a tunnel part TL may be formed, and a preliminary insulation layer 184j and a vertical sacrificial layer 183c may be formed.

In further detail, the tunnel part TL may be formed by removing a part of the sacrificial insulation layer 130s exposed through the penetrating portion OH for the wire in a horizontal direction. When the etching material is inflowed through the penetrating portion OH for the wire, the sacrificial insulation layer 130s adjacent to the penetrating portion OH for the wire may be etched in the horizontal direction, thereby forming the tunnel part TL. At this time, the etching may also be performed in the vertical (e.g., upward and downward) directions of the sacrificial insulation layer 130s to form a tunnel part TL with a slightly thicker thickness than that of the sacrificial insulation layer 130s. In this way, since the tunnel part TL is formed by the etching in the horizontal direction through the penetrating portion OH for the wire, the side of the tunnel part TL may have a slope of relatively small size or may include a convex shape or a rounded portion.

The tunnel part TL may be formed to have a relatively shorter length in a horizontal direction in the pad portions PP of the connection gate electrode 130c and may be formed to have a relatively long length in the horizontal direction in the remaining gate electrodes 130r. For this purpose, after forming the tunnel part TL, a sacrificial insulation layer may be additionally formed within the penetrating portion OH for the wire and tunnel part TL.

Subsequently, a preliminary insulation layer 184j and a vertical sacrificial layer 183c may be filled in the tunnel part TL and the penetrating portion OH for the wire.

A part of the preliminary insulation layer 184j may remain to form the insulating pattern 184i. For example, the preliminary insulating layer 184j may include a first preliminary insulation layer 183a and a second preliminary insulation layer 183b. For example, the first preliminary insulation layer 183a may include a silicon oxynitride, and the second preliminary insulation layer 183b may include a silicon oxide. An oxidation treatment process may be performed on the first preliminary insulation layer 183a. In the first preliminary insulation layer 183a, a portion adjacent to the penetrating portion OH for the wire may be oxidized and changed to a silicon oxide layer, and a portion far from the penetrating portion OH for the wire may not be oxidized and remain as a silicon oxynitride layer. In FIG. 8H, the portion marked with a dotted line is a portion where the first preliminary insulation layer 183a is changed to a silicon oxide layer, and the portion marked with a solid line may be a remaining silicon oxynitride layer of the first preliminary insulation layer 183a.

The preliminary insulation layer 184j may be formed so as to not completely fill the tunnel part TL formed corresponding to the pad portion PP of the connection gate electrode (reference numeral 130c of FIG. 2, hereinafter the same) having a relatively large thickness, and to fill the tunnel part TL formed corresponding to the remaining gate electrode (reference numeral 130r of FIG. 2, hereinafter the same). This may be due to the relative thickness difference between the connection gate electrode and the remaining gate electrode. The preliminary insulation layer 184j may be formed such that the void (V) remains in at least a part thereof. The vertical sacrificial layer 183c may be formed to fill the remaining space in the penetrating portion OH for the wire. The vertical sacrificial layer 183c may include a material different from that of the preliminary insulation layer 184j and may include, for example, polysilicon, tungsten, and the like.

Subsequently, as shown in FIG. 8I, a sacrificial insulation layer (reference numerals 130s and 130t in FIG. 8G and FIG. 8H, hereinafter the same) may be replaced with a gate electrode 130 and a gate contact portion 184 may be formed. For example, the first and second gate stacking structures 120a and 120b may be formed by replacing the sacrificial insulation layers of the first and second stacking structures 120d and 120e with the gate electrodes 130.

First, an opening may be formed in an area corresponding to the separation structure (reference numeral 146 of FIG. 2, hereinafter the same) to extend through (e.g., pass through) the first and second gate stacking structures 120a and 120b. The sacrificial insulation layers 130s and 130t can be selectively removed by an etching process (e.g., a dry etching process) through an opening. In addition, the gate electrode 130 may be formed by filling a conductive material constituting the gate electrode 130 in a portion from which the sacrificial insulation layers 130s and 130t are removed. As a result, the areas where the sacrificial insulation layers 130s and 130t are positioned may be replaced with the gate electrodes 130. In this case, a process of forming the first blocking layer 156a may be further performed before the process of filling the conductive material constituting the gate electrode 130.

In this case, when the sacrificial insulation layer 130s is removed, the silicon oxynitride layer that is not oxidized and remains around the tunnel part (reference numeral TL in FIG. 8H, hereinafter the same) may be removed. When forming the first blocking layer 156a and/or the gate electrode 130, the first blocking layer 156a and/or gate electrode 130 may be formed on a portion from which the silicon oxynitride layer is removed. As a result, the insulating pattern 184i may have a structure as shown in the enlarged view of FIG. 7B.

According to some embodiments, an opening may be formed to expose the horizontal insulation layer 116. In the etching process through the opening, at least a portion of the horizontal insulation layer 116 and a portion of the gate dielectric layer 150 may be removed, and a material constituting the first horizontal conductive layer 112 may be filled the portion from which the portions of the gate dielectric layer 150 and the horizontal insulation layer 116 are removed to form the first horizontal conductive layer 112.

In addition, an insulating material may be filled in the opening to form a separation structure 146.

Subsequently, a part of the vertical sacrificial layer (reference numeral 183c of FIG. 8H, hereinafter the same) and a part of the preliminary insulation layer (reference numeral 184j of FIG. 8H, hereinafter the same) may be removed, and the gate contact portion 184 may be formed by filling a conductive material in portions from which the parts of the vertical sacrificial layer and the preliminary insulation layer are removed.

In further detail, after selectively removing the vertical sacrificial layer 183c, a portion of the preliminary insulation layer 184j may be removed. At this time, all of the preliminary insulation layer 184j formed on the pad portions PP of the connection gate electrode 130c may be removed, and the preliminary insulation layer 184j formed on the tunnel part TL of the remaining gate electrode 130r may remain to form an insulating pattern 184i.

Subsequently, the gate contact portion 184 may be formed by depositing a conductive material in the penetrating portion OH for the wire. The gate contact portion 184 may have a connection portion 184c protruded to the inner surface of the pad portions PP. After that, a second wire part 180 connected to the channel structure CH may be further formed.

According to some embodiments, portions of the bottom 120p of the upper structure adjacent to the channel structure CH and adjacent to the gate contact portion 184 may have different structures or different materials. Therefore, the semiconductor device 10 that satisfies the required properties of the channel structure CH and the gate contact portion 184 may be manufactured by a simple process.

Hereinafter, a semiconductor device according to some embodiments will be described in more detail with reference to FIGS. 9 to 13. For parts that are the same as or very similar to those above-described parts, the detailed description may be omitted, and only other parts are explained in detail.

FIG. 9 illustrates a partial plan view showing a surface corresponding to an upper surface of a bottom gate electrode in a semiconductor device according to some embodiments. FIG. 9 shows the part corresponding to FIG. 6B.

Referring to FIG. 9, in some embodiments, the bottom insulating portion 132p may have a line shape or a bar shape extending in the elongation direction (e.g., Y-axis of the drawing) of the bottom gate electrode 130p. According to this, since the bottom insulating portion 132p may be formed to have a sufficient area, it is possible to more effectively respond to the deviated or misaligned of the gate contact portion 184. For example, the bottom insulating portion 132p may be formed to be in contact with at least one dummy structure DH and/or to extend around (e.g., surround) at least one dummy structure DH. By this shape, the bottom insulating portion 132p may be distinguished from the insulating pattern 184i of the gate contact portion 184.

In this case, since electrical connection passages are provided on both sides of the bottom insulating portion 132p in the width direction (e.g., X-axis direction of the drawing) of the bottom gate electrode 130p, the electrical connection may be maintained even if the bottom insulating portion 132p is formed.

FIG. 10 illustrates a partial plan view showing a surface corresponding to an upper surface of a bottom gate electrode in a semiconductor device according to some embodiments. FIG. 10 shows the part corresponding to one pad area PA in FIG. 5.

Referring to FIG. 10, in some embodiments, the bottom insulating portion 132p may have a line shape or bar shape extending in the elongation direction (e.g., Y-axis of the drawing) of the bottom gate electrode 130p, and may have a shape extending around (e.g., surrounding) a plurality of gate contact portions 184. According to this, since the bottom insulating portion 132p is formed to have a sufficient area, it is possible to more effectively respond to the deviated or misaligned of the gate contact portion 184. For example, the bottom insulating portion 132p may be formed to extend around (e.g., surround) at least one dummy structure DH. The bottom insulating portion 132p may be distinguished from the insulating pattern 184i of the gate contact portion 184 by this shape.

As such, when the bottom insulating portion 132p has the shape extending around (e.g., surrounding) the plurality of gate contact portion 184, since the electrical connection passage is provided on both sides of the bottom insulating portion 132p in the width direction of the bottom gate electrode 130p, even if the bottom insulating portion 132p is formed, the electrical connection may be maintained.

FIG. 10 illustrates that the bottom insulating portion 132p is formed as a whole to correspond to one pad area PA, however the bottom insulating portion 132p may be formed to correspond to a part of the plurality of gate contact portions 184 positioned in one pad area PA.

FIGS. 11A and 11B illustrate enlarged views of a part of a cell array area and a part of a connection area in a semiconductor device according to some embodiments. FIGS. 11A and 11B show the parts corresponding to FIGS. 7A and 7B.

Referring to FIGS. 11A and 11B, in some embodiments, the bottom insulating portion 132p may be formed to extend through (e.g., penetrate) the bottom gate electrode 130p and one or a plurality of adjacent gate electrodes 130q positioned on the bottom gate electrode 130p. For example, the bottom insulating portion 132p may be on side surfaces of the bottom gate electrode 130p and on or a plurality of adjacent gate electrodes 130q.

That is, the bottom insulation layer 132q may include an interlayer insulating layer 132m positioned on one or the plurality of adjacent gate electrodes 130q positioned on the bottom gate electrode 130p and a bottom insulating portion 132p extending through (e.g., penetrating) the bottom gate electrode 130p and one or the plurality of adjacent gate electrode 130q from the interlayer insulating layer 132m and extending to the bottom 120p. In this case, the bottom insulation layer 132q may include the interlayer insulating layer 132m and the bottom insulation portion 132p, and the bottom insulation portion 132p and the interlayer insulating layer 132m may have an integrated structure.

In this way, when the bottom insulating portion 132p is formed to penetrate the plurality of gate electrodes 130 (e.g., 130p and 130q), the insulating distance between the gate contact portion 184 and the gate electrodes 130 may be more stably secured by sufficiently securing the thickness or height of the bottom insulating portion 132p. That is, FIGS. 7A and 7B illustrates that the bottom insulating portion 132p is formed passing through one bottom gate electrode 130p, but the embodiment of the present inventive concept is not limited thereto.

The bottom insulation layer 132q of the above structure may be formed by any of various processes. For example, in the process corresponding to FIG. 8B, the bottom insulating sacrificial layer for the formation of the bottom gate electrode 130p may be formed, and then, one or plurality of interlayer insulating layers and one or plurality of insulating sacrificial layers for the formation of one or the plurality of adjacent gate electrodes 130q may be alternately stacked. At this time, an insulating sacrificial layer may be positioned at the uppermost. Also, in the process corresponding to FIG. 8C, a gate removed portion (reference numeral 130h of FIG. 8C, hereinafter the same) may be formed to penetrate the bottom insulating sacrificial layer, the interlayer insulating layer, and the sacrificial insulation layer, in the process corresponding to FIG. 8D, an insulating material may be formed on the insulating sacrificial layer while filling the gate removed portion 130h, thereby forming the bottom insulation layer 132q having the structure in which the bottom insulating portion 132p and the interlayer insulating layer 132m are integrated. However, the embodiment of the present inventive concept is not limited thereto.

FIG. 12 illustrates a partial plan view showing a surface corresponding to an upper surface of a bottom gate electrode in a semiconductor device according to some embodiments.

Referring to FIG. 12, in some embodiments, the bottom insulating portion 132p may be formed only in some parts of the plurality of pad areas PA, and the bottom insulating portion 132p may not be formed in the other parts of the plurality of pad areas PA.

For example, in the pad area (e.g., a second pad area PA2) in which an upper structure is composed of a connection structure and a lower structure is composed of an insulating structure among a plurality of pad areas PA, the bottom insulating portion 132p may be positioned at the bottom of the upper structure. Here, the connection structure may mean a structure provided with a connection gate electrode (reference numeral 130c in FIG. 2, hereinafter the same), and an insulating structure may mean an insulating structure without the connection gate electrode 130c. In other pad areas (e.g., a first pad area PA1), the bottom insulating portion 132p may not be formed at the bottom of the upper structure.

In the connection structure, a second upper penetrating portion for forming the gate contact portion 184 may be formed to extend (e.g., pass) through the pad insulating portion 132i that may be made of an oxide. When the second upper penetrating portion is formed on the pad insulating portion 132i that is made of oxide in the etching process, the threshold size of the second upper penetrating portion may increase due to the oxide bowing phenomenon. In this way, when the connection structure constitutes the upper structure, the threshold size of the second upper penetrating portion at the bottom of the upper structure may greatly increase, and the problem of the deviated or misalignment of the gate contact portion may appear more severe. In some embodiments, when the connection structure constitutes the upper structure, the bottom insulating portion 132p may be formed at the bottom of the upper structure, so that the bottom threshold size of the second upper penetrating portion may be effectively reduced. Accordingly, problems caused by the deviation or misalignment of the gate contact portion 184 may be reduced.

In some embodiments, when the insulating structure constitutes the upper structure, since there is little possibility that the bottom threshold size of the second upper penetrating portion greatly increases at the bottom of the upper structure, the bottom insulating portion 132p may not be formed.

However, the present inventive concept is not limited thereto. Accordingly, regardless of whether the upper structure is the connection structure or the insulating structure, the bottom insulating portion 132p may be formed at the bottom of the upper structure in at least one of the plurality of pad areas PA, and the bottom insulating portion 132p may not be formed in the other pad areas PA.

FIG. 13 illustrates partial cross-sectional views showing a semiconductor device according to some embodiments. FIG. 13 shows the part corresponding to FIG. 2.

Referring to FIG. 13, in some embodiments, the gate stacking structure 120 may include first to third gate stacking structures 120a, 120b, and 120c sequentially stacked on the second substrate 110. The bottom insulating portion 132p may be positioned adjacent to the gate contact portion 184 in the bottom 120p of the upper structure (e.g., 120b and/or 120c).

Here, with reference to one bottom 120p, the gate stacking structure positioned at the lower side may be referred to as a lower structure, and the gate stacking structure positioned at the upper side may be referred to as an upper structure. In the first and second gate stacking structures 120a and 120b, the first gate stacking structure 120a may be the lower structure, and the second gate stacking structure 120b may be the upper structure. In the second and third gate stacking structures 120b and 120c, the second gate stacking structure 120b may be the lower structure, and the third gate stacking structure 120c may be the upper structure.

FIG. 13 shows that the bottom insulating portion 132p may be formed on the bottom 120p of the second gate stacking structure 120b and on the bottom 120p of the third gate stacking structure 120c. In this case, in the first and second gate stacking structures 120a and 120b, the lower structure (e.g., the first gate stacking structure 120a) may be the connection structure, and the upper structure (e.g., the second gate stacking structure 120b) may be the insulating structure. Also, in the second and third gate stacking structures 120b and 120c, the lower structure (e.g., the second gate stacking structure 120b) and upper structure (e.g., the third gate stacking structure 120c) may be the insulating structure, respectively.

As above-described, the bottom insulating portion 132p may be formed on the bottom 120p of the upper structure by corresponding to the pad area PA, regardless of whether the upper structure and the lower structure are the insulating structure or the connection structure. The bottom insulating portion 132p may be all formed in one or the plurality of the bottoms 120p in the plurality of pad areas PA or may be formed in at least one bottom 120p in one of the plurality of pad areas PA and may not be formed in the others. As such, the present inventive concept is not limited to the position of the bottom insulating portion 132p.

FIG. 13 illustrates that the gate stacking structure 120 includes the first to third gate stacking structures 120a, 120b, and 120c, however the gate stacking structure 120 may include four or more gate stacking structures.

An additional embodiment different from the above-described embodiments is described with reference to FIG. 14. In FIG. 14, except where otherwise indicated for the same or similar reference numerals of that of FIGS. 1 to 13, the description with reference to FIG. 1 to FIG. 13 may be applied as it is. Hereinafter, different parts from the description in the embodiment referring FIG. 1 to FIG. 13 are mainly described.

FIG. 14 illustrates a partial cross-sectional view showing a semiconductor device according to some embodiments.

Referring to FIG. 14, a semiconductor device according to some embodiments may have a chip to chip (C2C) structure bonded by a wafer bonding method. That is, after manufacturing a lower chip including a circuit area 200a formed on a first substrate 210 and manufacturing an upper chip including a cell area 100a formed on a second substrate 110a, they may be bonded to manufacture a semiconductor device.

The circuit area 200a may be provided with a first bonding structure 238 on a surface facing the cell area 100a above the first substrate 210, the circuit element 220, and the first wire part 230.

The cell area 100a may be provided with a second bonding structure 194 on a surface facing the circuit area 200a above the second substrate 110a, the gate stacking structure 120, the channel structure CH, and the second wire part 180.

The second substrate 110a may be a semiconductor substrate including a semiconductor material. For example, the second substrate 110a may be a semiconductor substrate formed of a semiconductor material or may be a semiconductor substrate on which a semiconductor layer is formed on a base substrate. For example, the second substrate 110a may be formed of single crystals, polysilicon, germanium, silicon-germanium, a silicon-on-insulator, or a germanium-on-insulator, but is not limited thereto.

In the gate stacking structure 120, the gate electrode 130 may include a lower gate electrode, a memory cell gate electrode, and an upper gate electrode sequentially positioned from the above of the second substrate 110a while being from the second substrate 110a toward the circuit area 200a. That is, as shown in FIG. 14, the gate stacking structure 120 is sequentially stacked on the lower part of the second substrate 110a on the drawing, thereby being disposed in a shape in which the gate stacking structure 120 shown in FIG. 1 to FIG. 3 is disposed in a form of being inverted upside down.

Accordingly, the channel pad 144 and the second wire part 180 positioned on the gate stacking structure 120 may be positioned adjacent to the circuit area 200a. A second bonding structure 194 electrically connected to the second wire part 180 may be provided on the surface facing the circuit area 200a. The area of the surface facing the circuit area 200a other than the second bonding structure 194 may be covered by the insulation layer 196. As such, in the cell area 100a, the second wire part 180 and the second bonding structure 194 may be positioned to face the circuit area 200a.

For example, the second bonding structure 194 of the cell area 100a and/or the first bonding structure 238 of the circuit area 200a may be made of, for example, aluminum, copper, tungsten, or an alloy including these. For example, as the first and second bonding structures 238 and 194 contain copper, the cell area 100a and the circuit area 200a may be bonded by a copper-to-copper bonding (for example, direct contact bonding).

FIG. 14 illustrates that the gate stacking structure 120 includes the first and second gate stacking structures 120a and 120b, but an embodiment is not limited thereto. Except as otherwise noted, the description for the structure of the gate stacking structure 120 and the channel structure CH described with reference to FIG. 1 to FIG. 13 may be applied as it is. FIG. 14 illustrates that the electrical connection structure of the channel structure CH, the first and second horizontal conductive layers 112 and 114, and/or the second substrate 110 may be the same as that of FIG. 1. The present inventive concept is not limited thereto, and the electrical connection structure of the channel structure CH, the first and second horizontal conductive layers 112 and 114, and/or the second substrate 110 may be various.

The semiconductor device 20 according to some embodiments may include an input and output pad (not shown) and an input and output connection wire (not shown) electrically connected thereto. The input and output connection wires may be electrically connected to a portion of the second bonding structure 194. The input and output pads, for example, may be positioned on the insulation layer 198b that is on (e.g., cover) an upper surface (e.g., the outer surface) of the second substrate 110a. According to some embodiments, a separate input and output pad electrically connected to the circuit area 200a may be provided.

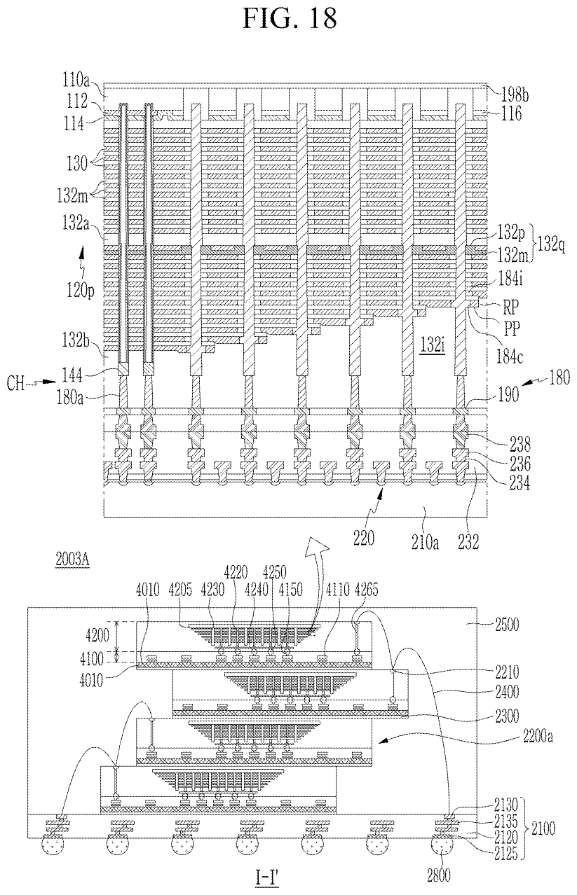

For example, the circuit area 200a and the cell area 100a may be a part corresponding to the first structure 1100F and the second structure 1100S of the semiconductor device 1100 included in the electronic system 1000 shown in FIG. 15, respectively. In some embodiments, the circuit area 200a and the cell area 100a may be an area including the first structure 4100 and the second structure 4200 of the semiconductor chip 2200a shown in FIG. 18, respectively.

An example of an electronic system including the semiconductor device as described above will be described in detail.

FIG. 15 illustrates a view schematically showing an electronic system including a semiconductor device according to some embodiments.

Referring to FIG. 15, an electronic system 1000 according to some embodiments may include a semiconductor device 1100 and a controller 1200 electrically connected to the semiconductor device 1100. The electronic system 1000 may be an electronic device including a storage device including one or a plurality of semiconductor devices 1100 or an electronic device including the storage device. For example, the electronic system 1000 may be a solid state drive device (SSD device), a universal serial bus (USB), a computing system, a medical device, or a communication device, including one or a plurality of semiconductor devices 1100.

The semiconductor device 1100 may be a non-volatile memory device, for example, may be the NAND flash memory device described with reference to FIG. 1 to FIG. 14. The semiconductor device 1100 may include a first structure 1100F and a second structure 1100S on the first structure 1100F. In some embodiments, the first structure 1100F may be disposed adjacent (e.g., next to) the second structure 1100S. The first structure 1100F may be a peripheral circuit structure including a decoder circuit 1110, a page buffer 1120, and a logic circuit 1130. The second structure 1100S may be a memory cell structure including a bit line BL, a common source line CSL, a word line WL, first and second gate upper lines UL1, and UL2, first and second gate lower lines LL1, and LL2, and a memory cell string CSTR between the bit line BL and the common source line CSL.

In the second structure 1100S, each of the memory cell strings CSTR may include lower transistors LT1 and LT2 adjacent to the common source line CSL, upper transistors UT1 and UT2 adjacent to the bit line BL, and a plurality of memory cell transistors MCT disposed between the lower transistors LT1 and LT2 and the upper transistors UT1 and UT2. The number of lower transistors LT1 and LT2 and the number of upper transistors UT1 and UT2 may be variously modified according to embodiments.

In some embodiments, the lower transistors LT1 and LT2 may include a ground selection transistor, and the upper transistors UT1 and UT2 may include a string selection transistor. The first and second gate lower lines LL1 and LL2 may be gate electrodes of the lower transistors LT1 and LT2, respectively. The word line WL may be a gate electrode of the memory cell transistor MCT, and the gate upper lines UL1 and UL2 may be gate electrodes of the upper transistors UT1 and UT2, respectively.

The common source line CSL, the first and second gate lower lines LL1 and LL2, the word line WL, and the first and second gate upper lines UL1 and UL2 may be electrically connected to the decoder circuit 1110 through a first connection wire 1115 extending to the second structure 1100S in the first structure 1100F. The bit line BL may be electrically connected to the page buffer 1120 through a second connection wire 1125 extending to the second structure 1100S in the first structure 1100F. The first and second connection wires 1115 and 1125 may extend in the first and second structures 1100F and 1100S.

In the first structure 1100F, the decoder circuit 1110 and the page buffer 1120 may execute a control operation on at least one memory cell transistor selected from among a plurality of memory cell transistors MCT. The decoder circuit 1110 and the page buffer 1120 may be controlled by the logic circuit 1130. The semiconductor device 1100 may communicate with the controller 1200 through an input and output pad 1101 electrically connected to the logic circuit 1130. The input and output pad 1101 may be electrically connected to the logic circuit 1130 through an input and output connection wire 1135 extending to the second structure 1100S in the first structure 1100F. The input and output connection wire 1135 may extend in the first and second structures 1100F and 1100S.

The controller 1200 may include, for example, a processor 1210, a NAND controller 1220, and a host interface 1230. According to some embodiments, the electronic system 1000 may include a plurality of semiconductor devices 1100, and in this case, the controller 1200 may control the plurality of semiconductor devices 1100.

The processor 1210 may control the overall operation of the electronic system 1000 including the controller 1200. The processor 1210 may operate according to a predetermined firmware and may access the semiconductor device 1100 by controlling the NAND controller 1220. The NAND controller 1220 may include a NAND interface 1221 that processes a communication with the semiconductor device 1100. Through the NAND interface 1221, a control instruction for controlling the semiconductor device 1100, a data to be written to the memory cell transistor MCT of the semiconductor device 1100, a data to be read from the memory cell transistor MCT of the semiconductor device 1100, and the like may be transmitted. The host interface 1230 may provide a communication function between the electronic system 1000 and an external host. When a control instruction is received from an external host through the host interface 1230, the processor 1210 may control the semiconductor device 1100 in response to the control instruction. As used hereinafter, the terms “external/outside configuration”, “external/outside device”, “external/outside power”, “external/outside signal”, or “outside” are intended to broadly refer to a device, circuit, block, module, power, and/or signal that resides externally (e.g., outside of a functional or physical boundary) with respect to a given circuit, block, module, system, or device.

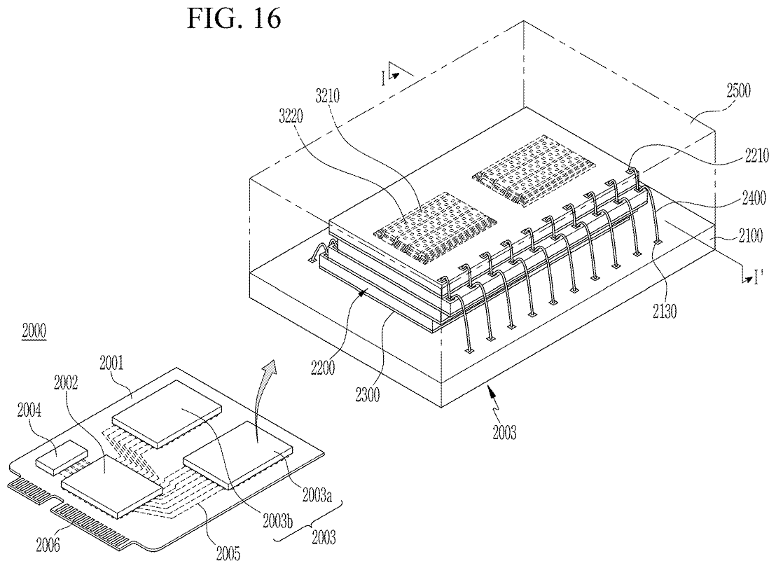

FIG. 16 illustrates a perspective view schematically showing an electronic system including a semiconductor device according to some embodiments.

Referring to FIG. 16, an electronic system 2000 according to some embodiments may include a main substrate 2001, and a controller 2002, at least one semiconductor package 2003, and a DRAM 2004, which are mounted on the main substrate 2001. The semiconductor package 2003 and the DRAM 2004 may be electrically connected to the controller 2002 by a wire pattern 2005 formed on the main substrate 2001.

The main substrate 2001 may include a connector 2006 including a plurality of pins coupled to an external host. The number and arrangement of a plurality of pins in the connector 2006 may vary depending on a communication interface between the electronic system 2000 and the external host. In some embodiments, the electronic system 2000 may communicate with the external host depending on one of interfaces such as universal serial bus (USB), peripheral component interconnect express (PCI-Express), serial advanced technology attachment (SATA), and M-Phy for universal flash storage (UFS). In some embodiments, the electronic system 2000 may operate by a power supplied from the external host through the connector 2006. The electronic system 2000 may further include a power management integrated circuit (PMIC) that distributes the power supplied from the external host to the controller 2002 and the semiconductor package 2003.

The controller 2002 may write the data to the semiconductor package 2003 or read the data from the semiconductor package 2003 and may improve the operation speed of the electronic system 2000.

The DRAM 2004 may be a buffer memory for mitigating a speed difference between the semiconductor package 2003, which is a data storage space, and the external host. The DRAM 2004 included in the electronic system 2000 may also operate as a kind of a cache memory and may provide a space for temporarily storing the data in the control operation for the semiconductor package 2003. When the electronic system 2000 includes the DRAM 2004, the controller 2002 may further include a DRAM controller for controlling the DRAM 2004 in addition to the NAND controller for controlling the semiconductor package 2003.

The semiconductor package 2003 may include first and second semiconductor packages 2003a and 2003b spaced apart from each other. The first and second semiconductor packages 2003a and 2003b may be semiconductor packages each including a plurality of semiconductor chips 2200. Each of the first and second semiconductor packages 2003a and 2003b may include a package substrate 2100, a semiconductor chip 2200 on the package substrate 2100, an adhesive layer 2300 disposed on the lower surface of each semiconductor chip 2200, a connection structure 2400 electrically connecting the semiconductor chip 2200 and the package substrate 2100, and a molding layer 2500 on (e.g., covering) the semiconductor chip 2200 and the connection structure 2400 on the package substrate 2100.

The package substrate 2100 may be a flexible printed circuit (FPC) including a package upper pad 2130. Each semiconductor chip 2200 may include an input and output pad 2210. The input and output pad 2210 may correspond to the input and output pad 1101 of FIG. 15. Each semiconductor chip 2200 may include a gate stacking structure 3210 and a channel structure 3220. The semiconductor chip 2200 may include the described semiconductor device respectively described with reference to FIGS. 1 to 14.

In some embodiments, the connection structure 2400 may be a bonding wire electrically connecting the input and output pad 2210 and the package upper pad 2130. Accordingly, in each of the first and second semiconductor packages 2003a and 2003b, the semiconductor chip 2200 may be electrically connected to each other by a bonding wire method and may be electrically connected to the package upper pad 2130 of the package substrate 2100. According to some embodiments, in each of the first and second semiconductor packages 2003a and 2003b, the semiconductor chip 2200 may be electrically connected to each other by a connection structure including a through electrode (e.g., a through silicon via, TSV) instead of the connection structure 2400 of the bonding wire type.

In some embodiments, the controller 2002 and the semiconductor chip 2200 may be included in one package. For example, the controller 2002 and the semiconductor chip 2200 may be mounted on a separate interposer substrate different from the main substrate 2001, and the controller 2002 and the semiconductor chip 2200 may be electrically connected to each other by a wire formed on the interposer substrate.

FIG. 17 and FIG. 18 are cross-sectional views showing a semiconductor package according to some embodiments. FIG. 17 and FIG. 18 respectively describe an embodiment of the semiconductor package 2003 of FIG. 16, and conceptually represent an area in which the semiconductor package 2003 of FIG. 16 is taken along a cutting line I-I′.

Referring to FIG. 17, in the semiconductor package 2003, the package substrate 2100 may be a flexible printed circuit (FPC). The package substrate 2100 may include a package substrate body part 2120, a package upper pad 2130 disposed at the upper surface of the package substrate body part 2120, a lower pad 2125 disposed at the lower surface of the package substrate body part 2120 or exposed through the lower surface, and an internal wire 2135 electrically connecting the package upper pad 2130 and the lower pad 2125 inside the package substrate body part 2120. The package upper pad 2130 may be electrically connected to the connection structure 2400. The lower pad 2125 may be electrically connected to a wire pattern 2005 of the main substrate 2010 of the electronic system 2000 like FIG. 16 through a conductive connection 2800.

The semiconductor chip 2200 may include a semiconductor substrate 3010, and a first structure 3100 and a second structure 3200 sequentially stacked on the semiconductor substrate 3010. The first structure 3100 may include a peripheral circuit area including a peripheral wire 3110. The second structure 3200 may include a common source line 3205, a gate stacking structure 3210 on the common source line 3205, a channel structure 3220 and a separation structure 3230 passing through the gate stacking structure 3210, a bit line 3240 electrically connected to the channel structure 3220, and a gate connection wire electrically connected to a word line (reference numeral WL of FIG. 15) of the gate stacking structure 3210.

In the semiconductor chip 2200 or the semiconductor device according to some embodiments, a part adjacent to the channel structure and a part adjacent to the gate contact portion at the bottom of the upper structure may have the different structures or materials, so that the channel structure and the gate contact portion may satisfy the required properties, respectively.

Each of the semiconductor chips 2200 may include a through wire 3245 electrically connected to the peripheral wire 3110 of the first structure 3100 and extending into the second structure 3200. The through wire 3245 may pass through the gate stacking structure 3210 and may be further disposed outside the gate stacking structure 3210. Each of the semiconductor chips 2200 may further include an input and output connection wire 3265 electrically connected to the peripheral wire 3110 of the first structure 3100 and extending into the second structure 3200, and an input and output pad 2210 electrically connected to the input and output connection wire 3265.

In some embodiments, a plurality of semiconductor chips 2200 in the semiconductor package 2003 may be electrically connected to each other by a connection structure 2400 in a form of a bonding wire. In some embodiments, the plurality of semiconductor chip 2200 or a plurality of parts constituting the same may be electrically connected by a connection structure including a through electrode (e.g., a through silicon via, TSV).

Referring to FIG. 18, in the semiconductor package 2003A, each semiconductor chip 2200a may include a semiconductor substrate 4010, a first structure 4100 on the semiconductor substrate 4010, and a second structure 4200 bonded to the first structure 4100 by a wafer bonding process on the first structure 4100.

The first structure 4100 may include a peripheral circuit area including a peripheral wire 4110 and a first bonding structure 4150. The second structure 4200 may include a common source line 4205, a gate stacking structure 4210 between the common source line 4205 and the first structure 4100, a channel structure 4220 and a separation structure 4230 penetrating the gate stacking structure 4210, and a second bonding structure 4250 electrically connected to the word line (reference numeral WL of FIG. 15, hereinafter the same) of the channel structure 4220 and gate stacking structure 4210, respectively. For example, the second bonding structure 4250 may be electrically connected to the channel structure 4220 and the word line WL, respectively, through a bit line 4240 electrically connected to the channel structure 4220 and a gate connection wire electrically connected to the word line WL. The first bonding structure 4150 of the first structure 4100 and the second bonding structure 4250 of the second structure 4200 may be bonded (e.g., contacting each other). The bonded portion of the first bonding structure 4150 and the second bonding structure 4250 may be formed of, for example, copper (Cu).

In the semiconductor chip 2200a or the semiconductor device according to the embodiment, a part adjacent to the channel structure and a part adjacent to the gate contact portion at the bottom of the upper structure may have a different structure or material, so that the channel structure and the gate contact portion may meet the required properties, respectively.

Each semiconductor chip 2200a may further include an input and output pad 2210 and an input and output connection wire 4265 under the input and output pad 2210. The input and output connection wire 4265 may be electrically connected to a portion of the second bonding structure 4250.

In some embodiments, a plurality of semiconductor chips 2200 in the semiconductor package 2003A may be electrically connected to each other by a connection structure 2400 in the form of a bonding wire. In some embodiments, the plurality of semiconductor chip 2200 or a plurality of parts constituting the same may be electrically connected by a connection structure including a through electrode.

While this disclosure has been described in connection with what is presently considered to be practical embodiments, it is to be understood that the invention is not limited to the disclosed embodiments. On the contrary, it is intended to cover various modifications and equivalent arrangements included within the scope of the appended claims

1. A semiconductor device comprising:
a circuit area including a peripheral circuit structure; and
a cell area on the circuit area,
wherein the cell area includes:
a cell array area;
a connection area;
a gate stacking structure including a plurality of gate electrodes, wherein the gate stacking structure includes an upper structure on the circuit area and a lower structure between the upper structure and the circuit area;
a plurality of channel structures that penetrates the gate stacking structure in the cell array area; and
a plurality of gate contact portions that penetrates the gate stacking structure in the connection area,
wherein the plurality of gate electrodes comprises a bottom gate electrode in a bottom portion of the upper structure,
wherein a gate contact portion among the plurality of gate contact portions is electrically connected to the circuit area and a connection gate electrode of the plurality of gate electrodes and is electrically insulated from remaining gate electrodes of the plurality of gate electrodes by an insulating pattern between the gate contact portion and the remaining gate electrodes,
wherein the bottom gate electrode in the cell array area is adjacent to a channel structure among the plurality of channel structures, and
wherein a bottom insulating portion having a structure and/or a material different from the insulating pattern is in the bottom portion of the upper structure and adjacent to the gate contact portion.

2. The semiconductor device of claim 1, wherein
the bottom gate electrode in the connection area is separated from the gate contact portion by the bottom insulating portion.

3. The semiconductor device of claim 1, wherein:
the bottom insulating portion penetrates the bottom gate electrode in the connection area; or
the bottom insulating portion penetrates the bottom gate electrode and an adjacent gate electrode that is on the bottom gate electrode in the connection area.

4. The semiconductor device of claim 1, wherein
the bottom gate electrode is in contact with the lower structure.

5. The semiconductor device of claim 1, wherein
the bottom insulating portion includes an oxide.

6. The semiconductor device of claim 1, further comprising:
an interlayer insulating layer on the bottom gate electrode in the connection area, wherein the bottom insulating portion and the interlayer insulating layer comprise an integrated unitary structure.

7. The semiconductor device of claim 1, wherein
in the upper structure, a ratio of a lower threshold size of the channel structure to an upper threshold size of the channel structure is greater than a ratio of a lower threshold size of the gate contact portion to an upper threshold size of the gate contact portion.

8. The semiconductor device of claim 1, wherein
a peripheral width of the bottom insulating portion is greater than a width of the insulating pattern.

9. The semiconductor device of claim 1, wherein
the bottom insulating portion has a circular shape, an elliptical shape, a polygon shape, or a line shape in a plan view.

10. The semiconductor device of claim 1, wherein
the bottom insulating portion at least partially extends around the gate contact portion in a plan view.

11. The semiconductor device of claim 1, wherein
the connection area includes a pad area in which the gate contact portion and at least one of the plurality of gate electrodes are connected to each other,
wherein the bottom insulating portion is in the pad area, and
wherein the upper structure includes the connection gate electrode.

12. The semiconductor device of claim 1, wherein
a side surface of the bottom insulating portion comprises an inclined surface relative to an upper surface of the lower structure to have a width that gradually narrows toward the upper surface of the lower structure or a vertical surface extending in a vertical direction that is perpendicular to the upper surface of the lower structure, and
a side surface of the insulating pattern includes a convex shape or a rounded portion.

13. The semiconductor device of claim 1, wherein
the bottom insulating portion includes a single insulating material, and
wherein the insulating pattern includes a plurality of insulation layers, a step profile on an upper surface or a lower surface of the insulating pattern, a part of a blocking layer, or a part of a gate electrode among the plurality of gate electrodes.

14. The semiconductor device of claim 1, wherein
the insulating pattern includes a void extending in a horizontal direction, and
wherein the bottom insulating portion is free of having the void extending in the horizontal direction.

15. The semiconductor device of claim 1, further comprising:
a dummy structure penetrates the gate stacking structure,
wherein the bottom insulating portion at least partially extends around the dummy structure in a plan view.

16. The semiconductor device of claim 1, wherein
the bottom insulating portion extends around the plurality of gate contact portions in a plan view.

17. An electronic system comprising:
a main substrate;
a semiconductor device on the main substrate; and
a controller electrically connected to the semiconductor device,
wherein the semiconductor device includes a circuit area including a peripheral circuit structure, and a cell area on the circuit area, and
wherein the cell area includes:
a cell array area;
a connection area;
a gate stacking structure including a plurality of gate electrodes, wherein the gate stacking structure includes a lower structure and an upper structure on the lower structure; and
a channel structure that penetrates the gate stacking structure in the cell array area,
wherein the plurality of gate electrodes includes a bottom gate electrode in a bottom portion of the upper structure,
wherein a gate contact portion in the connection area is electrically connected to the circuit area and a connection gate electrode of the plurality of gate electrodes and is electrically insulated from remaining gate electrodes of the plurality of gate electrodes by an insulating pattern between the gate contact portion and the remaining gate electrodes,
wherein the bottom gate electrode in the cell array area is adjacent to the channel structure, and
wherein a bottom insulating portion having a structure and/or a material different from the insulating pattern is in the bottom portion of the upper structure and adjacent to the gate contact portion.

18.-20. (canceled)

21. A semiconductor device comprising:
a circuit area including a peripheral circuit structure; and
a cell area on the circuit area,
wherein the cell area includes:
a cell array area;
a connection area that is adjacent to the cell array area;
a gate stacking structure including a plurality of gate electrodes, wherein the gate stacking structure includes an upper structure on the circuit area and a lower structure between the upper structure and the circuit area;
a plurality of channel structures that penetrates the gate stacking structure in the cell array area; and
a plurality of gate contact portions that penetrates the gate stacking structure in the connection area,
wherein the plurality of gate electrodes comprises a bottom gate electrode in a bottom portion of the upper structure,
wherein a gate contact portion among the plurality of gate contact portions is electrically connected to the circuit area and a connection gate electrode of the plurality of gate electrodes and is electrically insulated from remaining gate electrodes of the plurality of gate electrodes by an insulating pattern between the gate contact portion and the remaining gate electrodes,
wherein the bottom portion of the upper structure includes a first bottom portion adjacent to a channel structure among the plurality of channel structures in the cell array area,
wherein the bottom portion of the upper structure includes a second bottom portion adjacent to the gate contact portion in the connection area, and
wherein the first bottom portion includes a structure and/or a material different from the second bottom portion.

22. The semiconductor device of claim 21, wherein
the second bottom portion includes a bottom insulating portion having a structure and/or a material different from the insulating pattern.

23. The semiconductor device of claim 22, wherein
the bottom insulating portion penetrates the bottom gate electrode in the connection area.
